(19) United States
(12) Patent Application Publication
(10) Pub. No.: US 2026/0245633 A1
(43) Pub. Date: Aug. 20, 2026

(54) MULTIPLE READ BANDWIDTH FOR NON-VOLATILE MEMORY

(71) Applicant: Sandisk Technologies, Inc., Milpitas, CA (US)

(72) Inventors: Xiang Yang, Santa Clara, CA (US); Wei Cao, Fremont, CA (US); Ohwon Kwon, Pleasanton, CA (US); Richard New, Palo Alto, CA (US); Deepanshu Dutta, Fremont, CA (US)

(73) Assignee: Sandisk Technologies, Inc., Milpitas, CA (US)

(21) Appl. No.: 19/056,298

(22) Filed: Feb. 18, 2025

(51) Int. Cl. G11C 16/28; G11C 16/04; G11C 16/10

(52) U.S. Cl. CPC G11C 16/28; G11C 16/0483; G11C 16/102

(57) ABSTRACT

A system having high bandwidth non-volatile memory, such as NAND. The system senses the combined current of multiple memory cells and then determines a bit value for each cell based on the magnitude of the combined current. The system applies a reference voltage to multiple memory cells with one memory cell per NAND string and then senses a combined current of the multiple memory cells in response to the reference voltage. The system then determines a bit value of each of the multiple memory cells based on a magnitude of the combined current.

### BACKGROUND

The present disclosure relates to high bandwidth non-volatile memory.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery). One example of non-volatile memory is flash memory (e.g., NAND-type and NOR-type flash memory).

Users of non-volatile memory can program (e.g., write) data to the non-volatile memory and later read that data back. For example, a digital camera may take a photograph and store the photograph in non-volatile memory. Later, a user of the digital camera may view the photograph by having the digital camera read the photograph from the non-volatile memory.

Artificial Intelligence (AI) technology, particularly large models like GPT-4, DALL-E, and other foundation models, is enhancing human capability, revolutionizing multiple industries and addressing global challenges. The semiconductor industry has been fundamental to the AI revolution, providing the powerful, efficient hardware necessary to train and deploy increasingly complex models. The GPU (Graphics Processing Unit)+HBM (High Bandwidth Memory) architecture is one of the mainstream crucial architectures because it provides the performance, efficiency, and scalability necessary to handle massive AI workloads. A GPU+HBM architecture typically uses DRAM for the HBM. GPUs are designed to handle highly parallel computations, making them suitable for the vast matrix operations and data processing needs in AI tasks such as deep learning. HBM offers much higher bandwidth compared to traditional GDDR (Graphics Double Data Rate) memory, allowing GPUs to access more data per second. This directly accelerates the training and inference speeds for large AI models by mitigating bottlenecks in data access. The enhanced bandwidth of HBM also supports the high demands of model training, where massive amounts of data need to be loaded quickly and efficiently into GPU cores.

Although the GPU+HBM architecture has many advantages, it does come with notable drawbacks. A significant drawback of the GPU+HBM architecture is limited memory capacity. Although HBM offers high bandwidth, it has a relatively low memory capacity ceiling compared to other types of memory. As AI models continue to grow, the capacity limitations of HBM could become a bottleneck, especially for applications that require vast datasets or extremely large models. Another drawback of the GPU+HBM architecture is that the DRAM that is typically used for the HBM is very expensive.

### BRIEF DESCRIPTION OF THE DRAWINGS

Like-numbered elements refer to common components in the different figures.

FIG. 1A is a block diagram of one embodiment of a system having processing unit and high bandwidth flash units.

FIG. 1B is a block diagram depicting one embodiment of a high bandwidth flash unit.

FIG. 2A is a block diagram of one embodiment of a memory die that may be included in a high bandwidth flash unit.

FIG. 2B is a block diagram of one embodiment of an integrated memory assembly (also referred to as a memory die) that may be included in a high bandwidth flash unit.

FIGS. 3A and 3B show side views of embodiments of an HBF.

FIG. 3C depicts circuitry used to sense data from non-volatile memory.

FIG. 4 is a perspective view of a portion of one embodiment of a monolithic three-dimensional memory structure.

FIG. 4A is a block diagram of one embodiment of a memory structure having two planes.

FIG. 4B depicts a top view of a portion of one embodiment of a block of memory cells.

FIG. 4C depicts a cross-sectional view of a portion of one embodiment of a block of memory cells.

FIG. 4D depicts a cross-sectional view of a portion of one embodiment of a block of memory cells.

FIG. 4E is a cross-sectional view of one embodiment of a vertical column of memory cells.

FIG. 5 is a diagram depicting an embodiment of a system that senses combined currents of memory cells on different NAND strings.

FIG. 6 is a table depicting a mapping between combined currents and bit values for an embodiment of sensing pairs of memory cells together.

FIG. 7 depicts current (Icell) distributions for an embodiment of programming memory cells for double bandwidth read.

FIG. 8 depicts how programming of memory cells is performed in an embodiment.

FIG. 9 is a flowchart of one embodiment of programming process for programming current states.

FIG. 10A depicts cell current versus Vgs for a first group of memory cells that are programmed to either current distribution 702 or 704 in FIG. 7.

FIG. 10B depicts cell current versus Vgs for a second group of memory cells that are programmed to either current distribution 712 or 714 in FIG. 7.

FIG. 11 is a flowchart of one embodiment of a process of operating flash memory for double bandwidth during read.

FIG. 12 shows example current distributions for combined currents of two memory cells being sensed together.

FIG. 13 is a table that provides parameters associated with the sense capacitors in FIG. 14.

FIG. 14 is a schematic diagram of an embodiment of a sense amplifier that may be used to sense two memory cells on different NAND strings connected to the same bit line in a single read operation.

FIG. 15 is a timing diagram for various signals in the sense amplifier in FIG. 14.

FIG. 16A summarizes the parameters for sensing a first bit in a first cell by the sense amplifier in FIG. 14.

FIG. 16B summarizes the parameters for sensing a second bit in a second cell by the sense amplifier in FIG. 14.

FIG. 17 is a table that provides parameters associated with the sense times for an embodiment of the sense amplifier in FIG. 18.

FIG. 18 is a schematic diagram of an embodiment of a sense amplifier that may be used to sense two memory cells on different NAND strings connected to the same bit line in a single read operation.

FIG. 19 is a timing diagram for various signals for an embodiment of the sense amplifier in FIG. 18.

FIG. 20A summarizes the parameters for sensing a first bit in a first cell for an embodiment of the sense amplifier in FIG. 18.

FIG. 20B summarizes the parameters for sensing a second bit in a second cell for an embodiment of the sense amplifier in FIG. 18.

### DETAILED DESCRIPTION

A system having high bandwidth non-volatile memory is disclosed. The system senses the combined current of multiple memory cells and then determines a bit value for each cell based on the magnitude of the combined current. This sensing technique allows the multiple memory cells to be sensed in essentially the same time as it would conventionally take to sense and determine a bit value for a single memory cell. In an embodiment, the memory system applies a reference voltage to multiple memory cells with one memory cell per NAND string and then senses a combined current of the multiple memory cells in response to the reference voltage. The system then determines a bit value of each of the multiple memory cells based on a magnitude of the combined current.

In an embodiment, the system reads data from two memory cells on two different NAND strings that share the same bit line. The system connects the channels of the two NAND strings to the same bit line and applies a reference voltage to the two memory cells. The bit line current will therefore be the sum of the cell currents of the two memory cells in response to the reference voltage. In an embodiment, the cells are programmed to current states such that there are four possible magnitudes for the bit line current. In other words, the sum of the cell currents of the two memory cells may have four possible magnitudes. A sense amplifier demarcates between these four possible current magnitudes to determine a bit value each cell. Therefore, the read bandwidth essentially doubles from a conventional technique that reads a bit in one memory cell.

In one embodiment, the system programs the memory cells to current states, where a current state is defined by the magnitude of the cell current for a pre-defined Vgs. That is, the same magnitude is used for the memory cell Vgs regardless of the current state. In an embodiment, each memory cell may be programmed to either a non-conducting state to represent one bit value (e.g., “0”) or to a conducting state to represent the other bit value (e.g., “1”). A “non-conducting” current states means that the memory cell current will be very close to zero when the read reference voltage is applied to the memory cell. A “conducting” current state means that the memory cell current will conduct a significant current when the read reference voltage is applied to the memory cell. For a pair of memory cells to be read together, the current magnitude for conducting states are different. Using the different current magnitudes for conducting states results in the four possible current magnitudes for the combined currents from the two cells. These four possible combined current magnitudes correspond to the four possible values of two bits (00, 01, 10, 11).

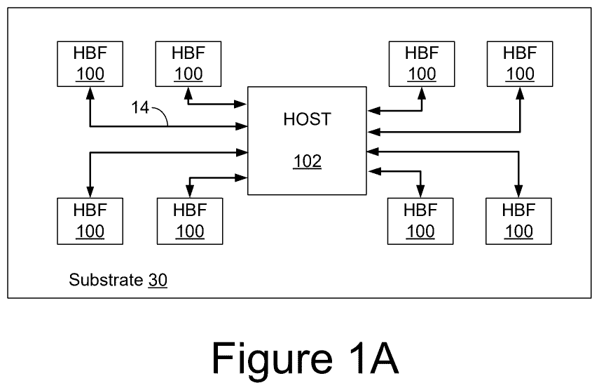

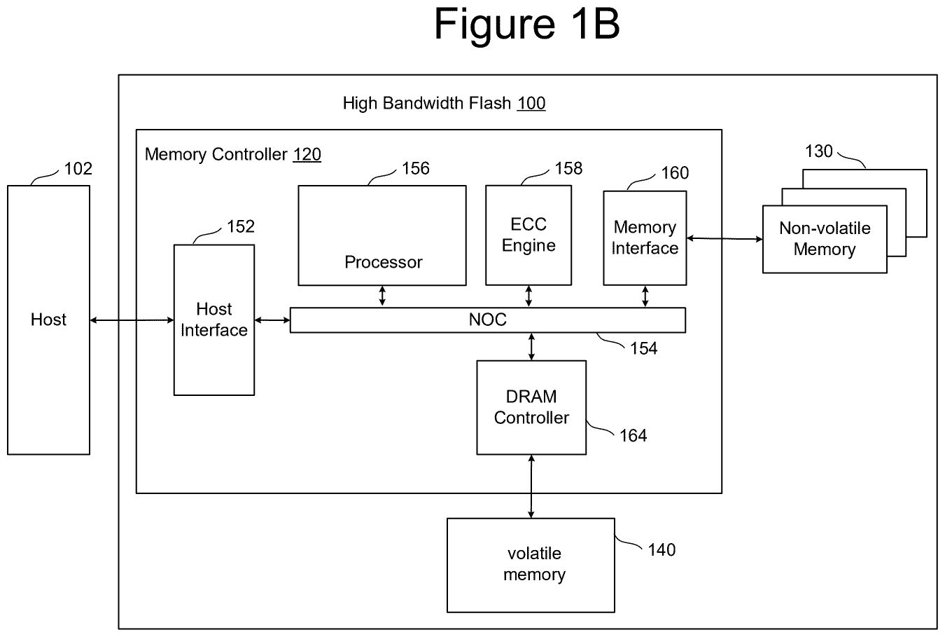

FIG. 1A is a block diagram of one embodiment of a system having a host 102 and high bandwidth flash (HBF) 100 units. The system may be used for an artificial intelligence applications, but is not limited thereto. Each HBF 100 contains non-volatile memory cells, such as NAND. Each HBF 100 also contains control logic to perform die level control such as applying voltages to control lines and sensing the memory cells. Optionally, the HBF 100 can include an ECC engine, memory controller, etc. Examples will be discussed in which the HBF 100 includes NAND, but the HBF 100 is not limited to NAND. Each HBF 100 is connected to the host 102 over a communication interface 14. The host 102 may include one or more processing units such as a central processing unit (CPU), graphics processing unit (GPU), etc. As one example, the communication interface 14 may be Universal Chiplet Interconnected Express (UCIe), although another protocol could be used. Each HBF 100 communicates with the host 102 to allow the host 102 to provide data to be stored in the HBF 100. The data provided by the host 102 may include parameters (e.g., weights) of an AI model. The HBF 100 may store the parameters in the HBF 100. The HBF 100 may encode the data prior to storing in high-bandwidth non-volatile memory. During the inferencing stage, the parameters (e.g., weights) of an AI model may be read from the HBF 100.

The HBF 100 and the host 102 may reside on a substrate 30. The substrate 30 may be, for example, a printed circuit board (PCB) or an interposer. The electrical connections between the host 102 and the HBF 100 may be made by, for example, PCB traces if the substrate 30 is a PCB. The substrate 30 may optionally be an interposer. However, the system does not need any interposers within the HBF 100.

FIG. 1B is a block diagram of one embodiment of a HBF 100 that implements the proposed technology described herein. HBF 100 is connected to host 102. The HBF 100 may implement one of the HBF 100 in FIG. 1A. The host 102 may be the host 102 in FIG. 1A. The host 102 may include, for example, a CPU, GPU, etc. In an embodiment, the host 102 provides parameters (e.g., weights) of an AI model, which the memory controller 120 stores in the non-volatile memory 130.

The components of HBF 100 depicted in FIG. 1B are electrical circuits. HBF 100 includes a memory controller 120 connected to non-volatile memory 130 and local high speed volatile memory 140 (e.g., DRAM). Local high speed volatile memory 140 is used by memory controller 120 to perform certain functions. For example, local high speed volatile memory 140 may be used for buffers to temporarily store data read from the memory 130.

Memory controller 120 comprises a host interface 152 that is connected to and in communication with host 102. In one embodiment, host interface 152 implements a UCIe interface. Other interfaces can also be used. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and DRAM controller 164. DRAM controller 164 is used to operate and communicate with local high speed volatile memory 140 (e.g., DRAM). In other embodiments, local high speed volatile memory 140 can be SRAM or another type of volatile memory.

ECC engine 158 performs error correction. For example, ECC engine 158 performs data encoding and decoding, as per the implemented ECC technique. The ECC engine 158 may be used to encode the parameters (e.g., weights) received from the host 102 prior to storage in the non-volatile memory 130. In an embodiment, the ECC engine 158 contains a number of individual ECC circuits (also referred to as ECC engines) that may be operated in parallel. Therefore, ECC engine 158 is able to decode data from more than one memory die in parallel. The ECC engine 158 could also be used to decode data from different planes of the same memory die in parallel. The ECC engine 158 may be implemented with hardware and/or software. In an embodiment, ECC engine 158 contains one or more custom and dedicated hardware circuits. In one embodiment, ECC engine 158 can include a processor that can be programmed. In an embodiment, the function of ECC engine 158 is implemented by processor 156.

Processor 156 performs the various controller memory operations, such as programming, erasing, reading, and memory management processes (e.g., data refresh). Processor 156 oversees the storage of the parameters (e.g., weights) for the AI model in the memory 130, as well as the retrieval of the parameters when inferencing is to be performed. Processor 156 provides the data read from the memory 130 to the ECC engine 158. After successful decoding, the decoded data is provided to the inference engine 162.

In one embodiment, processor 156 is programmed by firmware. In other embodiments, processor 156 is a custom and dedicated hardware circuit without any software. In some embodiments, a portion of the non-volatile memory 130 is made available for the host 102 to store and retrieve data. However, it is not required that the host 102 be permitted to retrieve data from the non-volatile memory 130. If host is permitted to store and retrieve data, the processor 156 may also implement a translation module, as a software/firmware process or as a dedicated hardware circuit. The memory controller 120 (e.g., the translation module) may perform address translation between logical addresses used by the host and physical addresses used by the memory dies. One example implementation is to maintain tables (e.g., logical to physical or L2P tables) that identify the current translation between logical addresses and physical addresses. An entry in the L2P table may include an identification of a logical address and corresponding physical address.

Memory interface 160 communicates with non-volatile memory 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

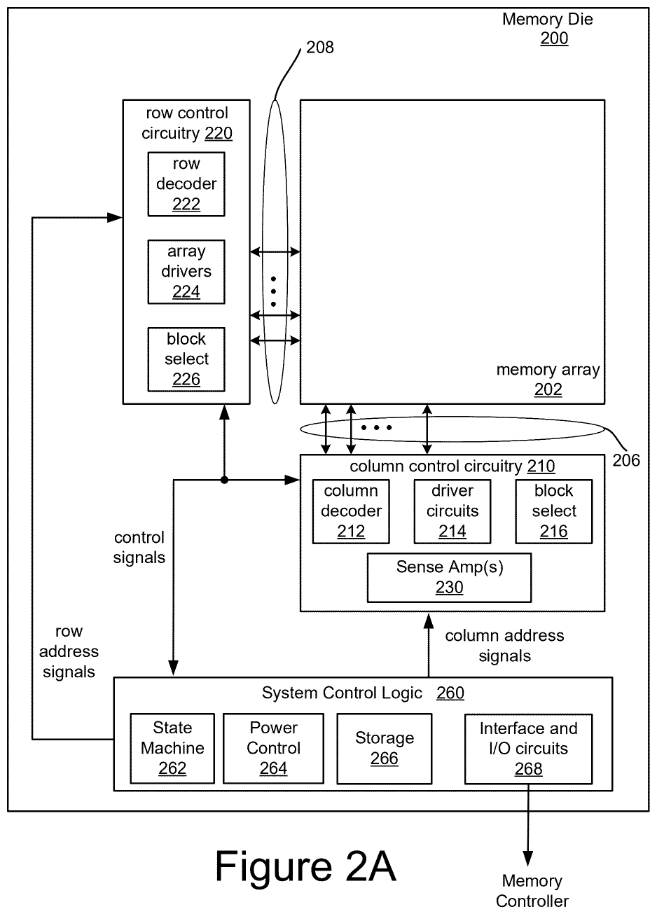

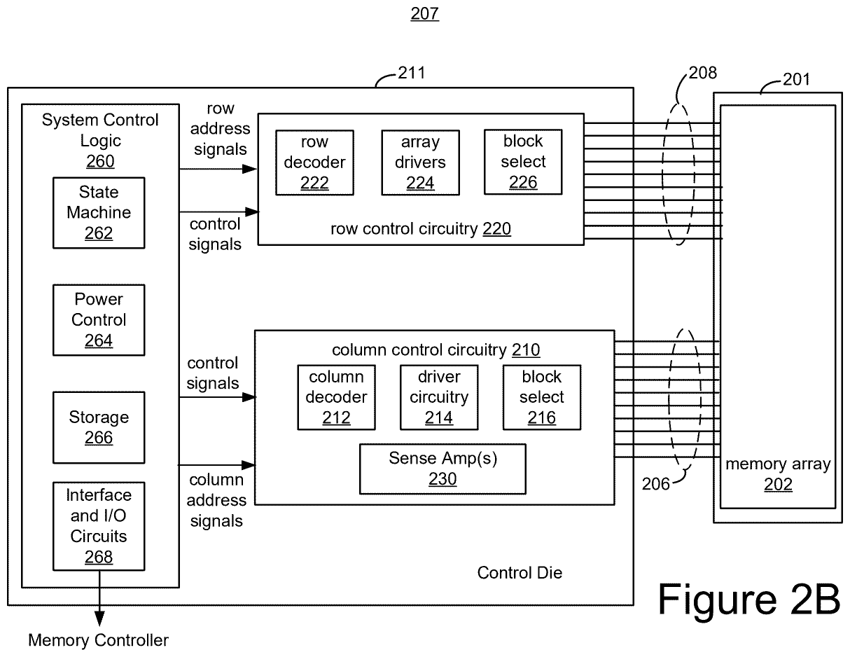

In one embodiment, non-volatile memory 130 comprises one or more memory die. FIG. 2A is a functional block diagram of one embodiment of a memory die 200 that comprises non-volatile memory 130. Each of the one or more memory die of non-volatile memory 130 can be implemented as memory die 200 of FIG. 2A. The components depicted in FIG. 2A are electrical circuits. Memory die 200 includes a memory array 202 that can comprise non-volatile memory cells, as described in more detail below. The array terminal lines of memory array 202 include the various layer(s) of word lines organized as rows, and the various layer(s) of bit lines organized as columns. However, other orientations can also be implemented. Memory die 200 includes row control circuitry 220, whose outputs 208 are connected to respective word lines of the memory array 202. Row control circuitry 220 receives a group of M row address signals and one or more various control signals from System Control Logic circuit 260, and typically may include such circuits as row decoders 222, array terminal drivers 224, and block select circuitry 226 for both reading and writing (programming) operations. Row control circuitry 220 may also include read/write circuitry. Memory die 200 also includes column control circuitry 210 including sense amplifier(s) 230 whose input/outputs 206 are connected to respective bit lines of the memory array 202. Although only single block is shown for array 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers.

System control logic 260 receives data and commands from memory controller 120 and provides output data and status to the host. In some embodiments, the system control logic 260 (which comprises one or more electrical circuits) include state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations and may include charge pumps and regulator circuit for creating regulating voltages. System control logic 260 includes storage 266 (e.g., RAM, registers, latches, etc.), which may be used to store parameters for operating the memory array 202.

Commands and data are transferred between memory controller 120 and memory die 200 via memory controller interface 268 (also referred to as a “communication interface”). Memory controller interface 268 is an electrical interface for communicating with memory controller 120 and includes one or more Input/Output (“I/O”) circuits. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed dies that are then bonded together. More specifically, the memory structure 202 can be formed on one die (referred to as the memory array die) and some or all of the peripheral circuitry elements, including one or more control circuits, can be formed on a separate die (referred to as the control die). For example, a memory array die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory array die to be optimized individually according to its technology. For example, a NAND memory array die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory array die and one control die, other embodiments can use more die, such as two memory array die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207, which is another example of a memory die. One or more integrated memory assemblies (one or more memory die) 207 may be used to implement the non-volatile memory 130 of HBF 100. The integrated memory assembly (or memory die) 207 includes two types of semiconductor die (or more succinctly, “die”). Memory array die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory array die 201. In some embodiments, the memory array die 201 and the control die 211 are bonded together.

FIG. 2B shows an example of the peripheral circuitry, including control circuits, formed in a peripheral circuit or control die 211 coupled to memory structure 202 formed in memory array die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory array die 201. In some embodiments, some of the circuitry in the system control logic 260 is located on the on the memory array die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory 2 die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including sense amplifier(s) 230 on the control die 211 coupled to memory structure 202 on the memory array die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory array die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory array die 201.

For purposes of this document, the phrases “a control circuit” or “one or more control circuits” can include any one of or any combination of memory controller 120, state machine 262, all or a portion of system control logic 260, all or a portion of row control circuitry 220, all or a portion of column control circuitry 210, a microcontroller, a microprocessor, and/or other similar functioned circuits. The control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

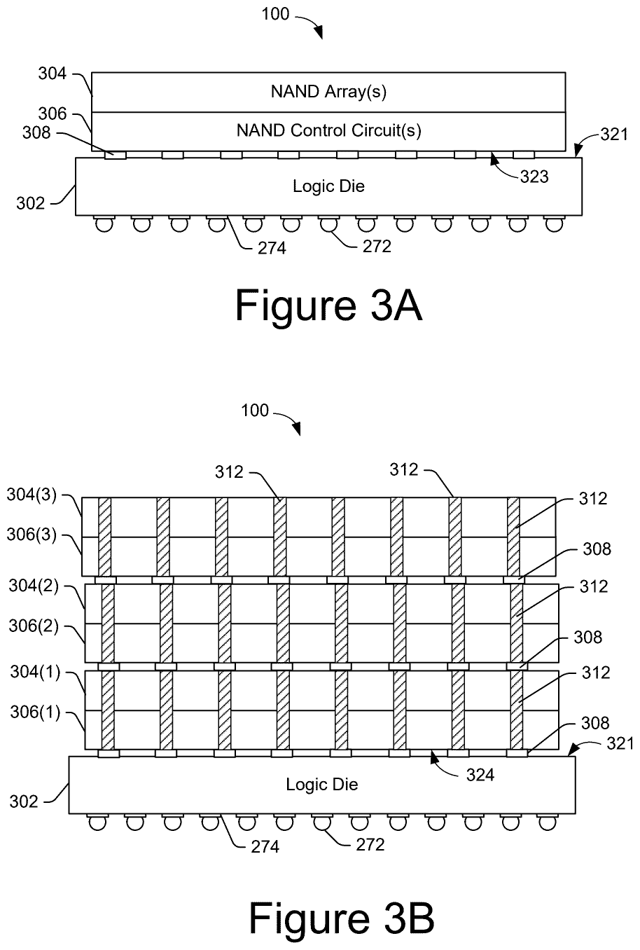

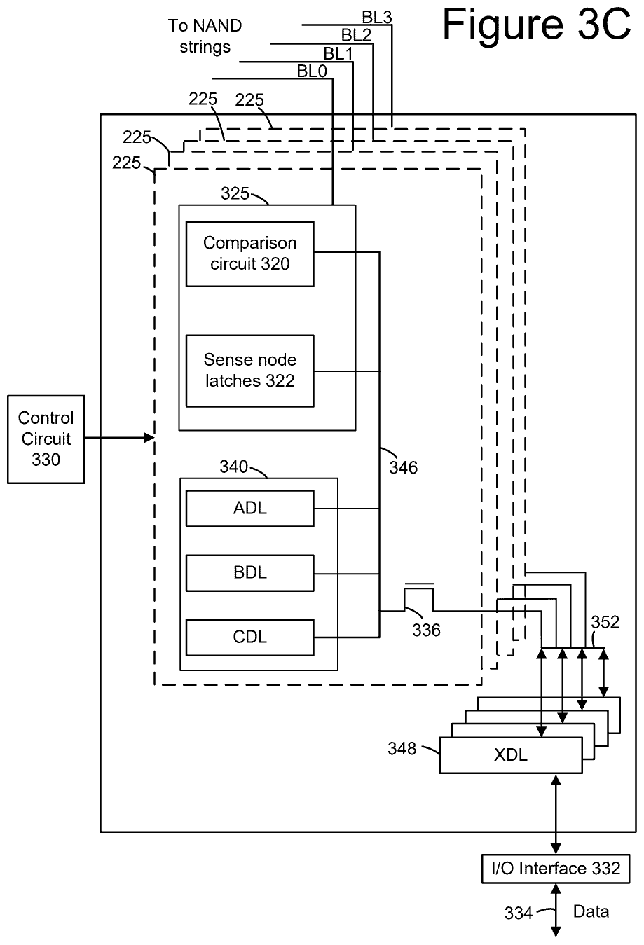

An embodiment includes an HBF 100 having a logic die and one or more NAND memory arrays. FIG. 3A shows a side view of one embodiment of an HBF 100 having a logic die 302, NAND array(s) 304, and a NAND control circuit 306. In an embodiment, NAND array(s) 304 and NAND control circuit 306 are implemented by memory die 200. NAND array(s) 304 may be implemented in memory array 202 and NAND control circuit 306 may be implemented by the combination of system control logic 260, row control circuitry 220, and column control circuitry 210. In an embodiment, NAND array(s) 304 is implemented by memory array die 201 and NAND control circuit 306 is implemented by control die 211.

The logic die 302 contains one or more ECC engines 158. In an embodiment, the logic die 302 implements the memory controller 120 of FIG. 1B. Microbumps 308 may be used to provide electrical connections between the NAND control circuit 306 and the logic die 302. An upper surface 321 of the logic die 302 opposes a lower surface 323 of the NAND control circuits 306. The upper surface 321 of the logic die 302 may be connected to the lower surface 323 of the NAND control circuit 306 by surface connections such as the microbumps 308.

In an embodiment, the logic die 302 resides on a substrate (e.g., PCB board). The substrate is not depicted in FIG. 3A. Solder balls 272 may optionally be affixed to contact pads 274 on a lower surface of logic die 302. The solder balls 272 may be used to couple the logic die 302 electrically and mechanically to a substrate such as a printed circuit board. Significantly, the logic die 302 is not required to have through silicon vias (TSVs) to allow communication with the NAND control circuit 306 or to access the NAND array 304.

FIG. 3A shows an embodiment in which there is a single layer having a NAND array 304 and NAND control circuit 306. In an embodiment in which memory die 200 has the NAND array(s) 304 and NAND control circuit(s) 306, the layer may contain one or more memory dies. For example, there may be two memory dies 200, four memory dies 200, etc. In an embodiment in which memory array die 201 has the NAND array(s) 304 and the control die 211 has the NAND control circuit(s) 306, there may be one or more memory array dies 201 and one or more control dies 211. The number of control dies 211 in a layer is not required to be equal to the number of memory array dies 201 in that layer. For example, one control die 211 may be used to control more than one memory array die 201 in a layer.

Some embodiments of an HBF 100 include a stack that contains a number of layers, with each layer having one or more NAND arrays and associated NAND control circuitry. FIG. 3B shows a side view of one embodiment in which the HBF 100 has a stack with three layers. A first layer includes NAND array(s) 304(1) and associated NAND control circuitry 306(1). A second layer includes NAND array(s) 304(2) and associated NAND control circuitry 306(2). A third layer includes NAND array(s) 304(3) and associated NAND control circuitry 306(3). There could be more or fewer than three layers in the stack. The discussion of the single layer in FIG. 3A applied to each layer in FIG. 3B. Thus, the architecture in FIG. 2A and/or 2B may be used in the HBF 100 in FIG. 3B. An upper surface 321 of the logic die 302 opposes a lower surface 324 of the NAND control circuits 306. The upper surface 321 of the logic die 302 may be directly connected to the lower surface 324 of the stack by surface connections such as the microbumps 308. Significantly, no interposer is needed between the logic die 302 and the stack.

Through silicon vias (TSV) 312 may be used to route signals through the stack. For example, TSVs 312 may be used to route signals through memory dies 200, memory array dies 201 and/or control dies 211 in the stack. The TSVs from the various die of the stack can be separately operated such that the logic die 302 can communicate with each die separately. The TSVs 312 may be formed before, during or after formation of the integrated circuits in the semiconductor dies (e.g., memory dies 200, memory array dies 201 and/or control dies 211). The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used. Note that the logic die 302 is not required to have TSVs. Since TSVs may occupy considerable area, the size of the logic die 302 may be reduced as it does not need TSVs. This savings in chip area may be used to add more circuitry such as inference engines and ECC engines.

FIG. 3C is a block diagram depicting one embodiment of a portion of column control circuitry 210 that contains a number of read/write circuits 225. Each read/write circuit 225 is partitioned into a plurality of sense amplifiers 325 and data latches 340. A control circuit 330 controls the read/write circuits 225. In one embodiment, each sense amplifier 325 is connected to a respective bit line. Each bit line is associated with a large number of different NAND strings. A select gate on the NAND string may be used to connect the NAND string channel to the bit line. For conventional memory cell sensing, the channel of a single NAND string is connected to the bit line at one point in time to allow the sense amplifier to sense a current in the bit line. This bit line in the conventional memory cell sensing reflects the state of a selected memory cell on the NAND string. In an embodiment, the channels of multiple NAND strings are connected to the same bit line at one point in time to allow the sense amplifier 325 to sense a combined current in the bit line from multiple selected memory cells. For example, the channels of two NAND strings may be connected to the same bit line to allow the sense amplifier 325 to sense a combined current from two selected memory cells on the respective NAND strings. Moreover, the sense amplifier 325 determines a bit value for each of the selected memory cells based on the magnitude of the combined current in the bit line.

Each sense amplifier 325 operates to provide voltages to one of the bit lines (see BL0, BL1, BL2, BL3) during program, verify, erase, and read operations. Sense amplifiers are also used to sense the condition (e.g., data state) of a memory cell in a NAND string connected to the bit line that connects to the respective sense amplifier. Moreover, in an embodiment, a sense amplifier is also used to sense the conditions (e.g., data states) of two memory cells on two respective NAND strings connected to the same bit line that connects to the respective sense amplifier.

Each sense amplifier 325 may have one or more sense nodes. During sensing, a sense node is charged up to an initial voltage, Vsense_init, such as 3V. For conventional sensing, the sense node is then connected to the bit line for a sense time, and an amount of change of voltage of the sense node is used to determine whether a memory cell is in a conductive or non-conducting state. In some embodiments, the memory cell current will discharge the voltage on the sense node.

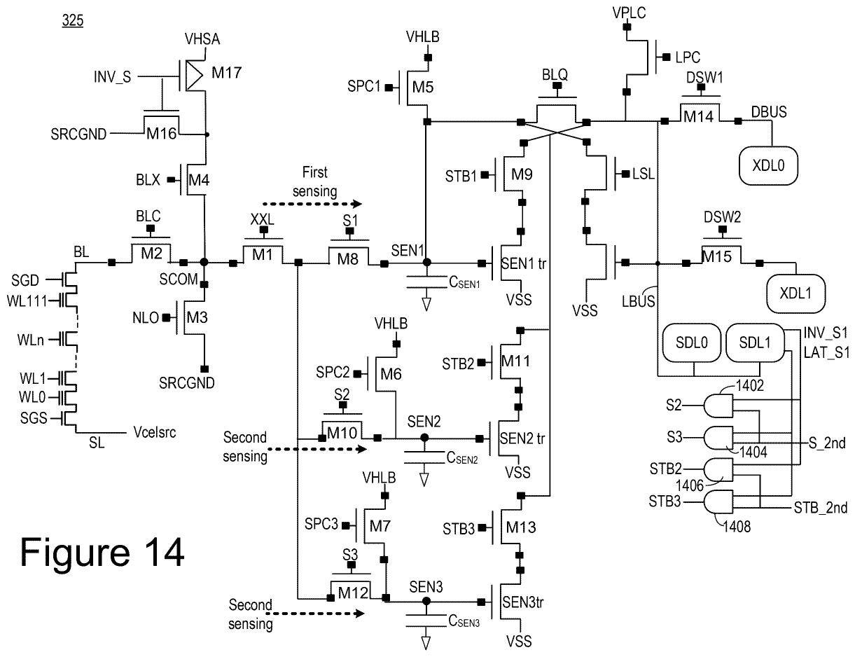

In an embodiment each sense amplifier has three sense nodes, which may be used to sense two bits in two memory cells based on the combined current of the two cells. First, one of the sense nodes is connected to the bit line for a sense time and an amount of change of voltage of the sense node is used to determine a bit for one of the cells. Then, either the second or third sense node is connected to the bit line for the sense time and an amount of change of voltage of the sense node is used to determine a bit for the other cell. Further details of an embodiment of a sense amplimer with three sense nodes for sensing two memory cells in a signal operation are described in connection with FIG. 14.

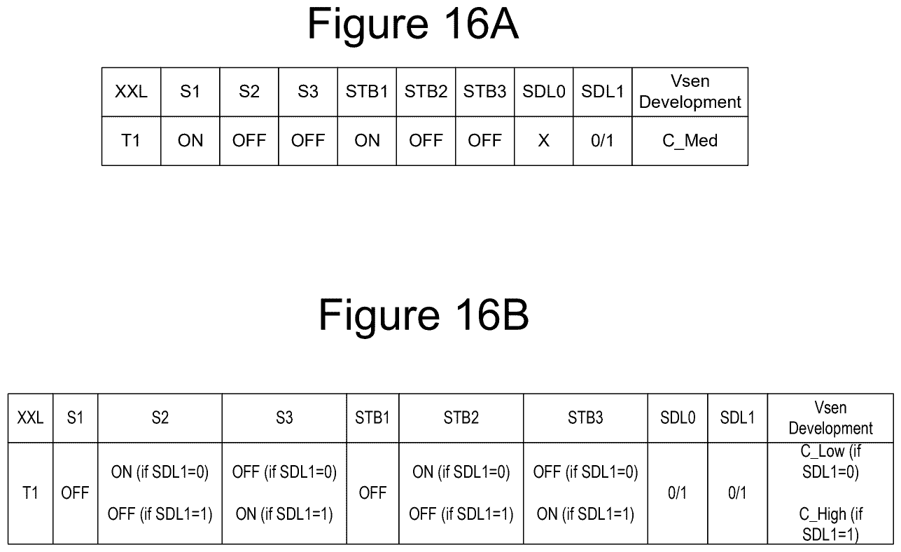

In an embodiment each sense amplifier has one sense node, which may be used to sense two bits in two memory cells based on the combined current of the two cells. First, the sense node is connected to the bit line for a sense time and an amount of change of voltage of the sense node is used to determine a bit for one of the cells. Then, the sense node is connected to the bit line for either a second or a third sense time and an amount of change of voltage of the sense node is used to determine a bit for the other cell. Further details of an embodiment of a sense amplimer with three sense nodes for sensing two memory cells in a signal operation are described in connection with FIG. 16.

The sense amplifier 325 has sense node latches 322 (also referred to as SDL latches). In an embodiment, there are two sense node latches 322 (e.g., SDL0, SDL1) to store a first bit value for a memory cell on a first NAND string and a second bit value for a memory cell on a second NAND string (which are connected to the same bit line). The amount of change of the sense node voltage indicates whether a bit line current exceeds a reference current, Iref. A larger change corresponds to a larger current. In particular, the comparison circuit 320 determines the amount of change of voltage on the relevant sense node by comparing the sense node voltage to a trip voltage after the sense time. The relevant sense node latch 322 is set to 0 or 1, for example, by the comparison circuit 320 based on comparing the sense node voltage to the trip voltage. A bit in one of the sense node latches 322 can also be used in a lockout scan to decide whether to set a bit line voltage to an inhibit or a program enable level in a next program loop.

The data latches 340 are coupled to the sense amplifier 325 by a local data bus 346. The data latches 340 include three latches (ADL, BDL, CDL) for each sense amplifier 325 in this example. More or fewer than three latches may be included in the data latches 340. In one embodiment, for programming each data latch 340 is used to store one bit to be stored into a memory cell and for reading each data latch 340 is used to store one bit read from a memory cell. In a three bit per memory cell embodiment, ADL stores a bit for a lower page of data, BDL stores a bit for a middle page of data, CDL stores a bit for an upper page of data. Each read/write circuit 225 is connected to an XDL latch 348 by way of an XDL bus 352. In this example, transistor 336 connects local data bus 346 to XDL bus 352. An I/O interface 332 is connected to the XDL latches 348. The XDL latch 348 associated with a particular read/write circuit 225 serves as an interface latch for storing/latching data from the memory controller.

Control circuit 330 performs computations, such as determining the data stored in the sensed memory cell and store the determined data in the set of data latches. Each set of data latches 340 is used to store data bits determined by control circuit 330 during a read operation, and to store data bits imported from the data bus 334 during a program operation which represent write data meant to be programmed into the memory. I/O interface 332 provides an interface between XDL latches 348 and the data bus 334.

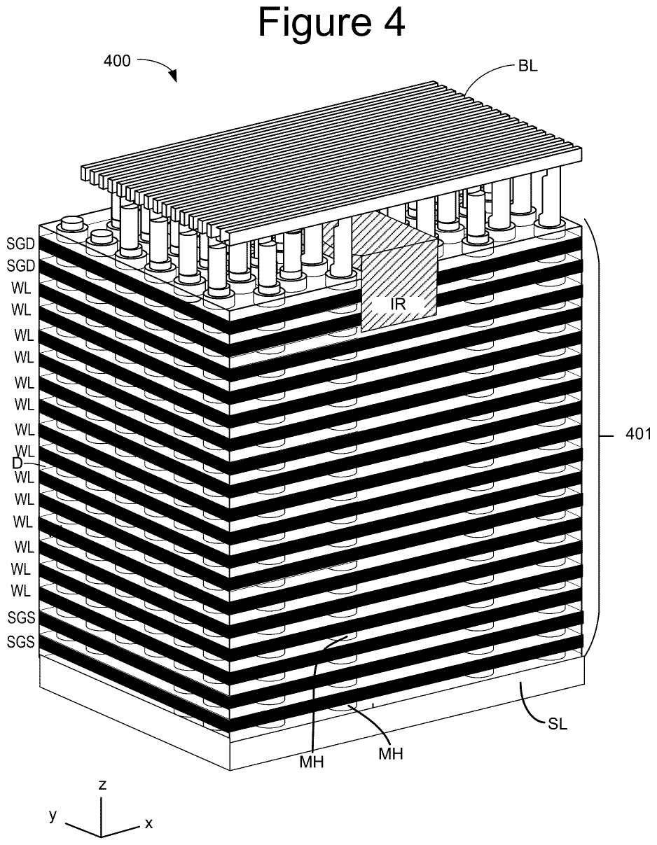

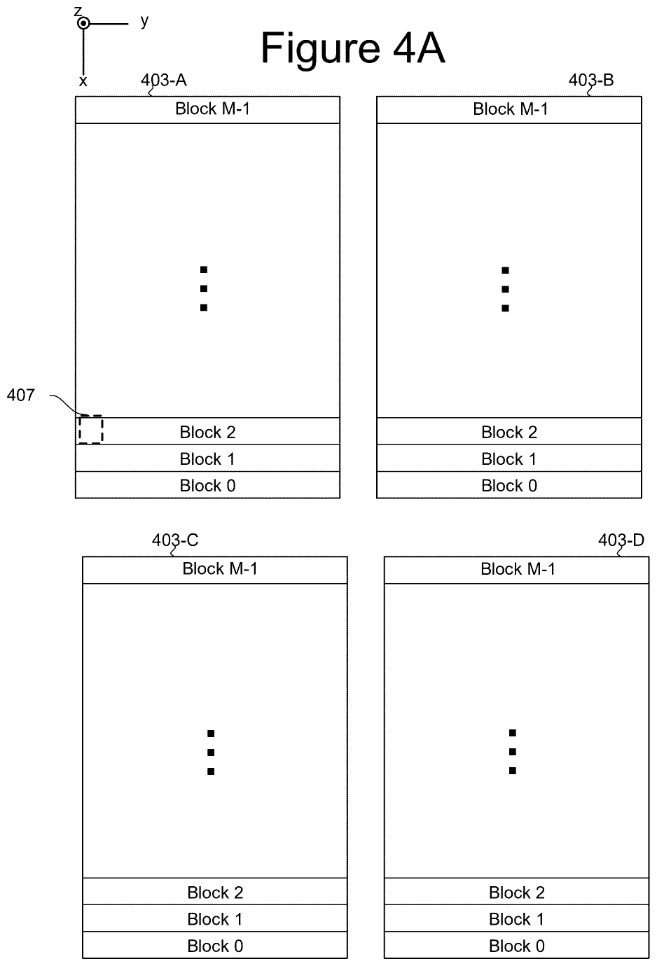

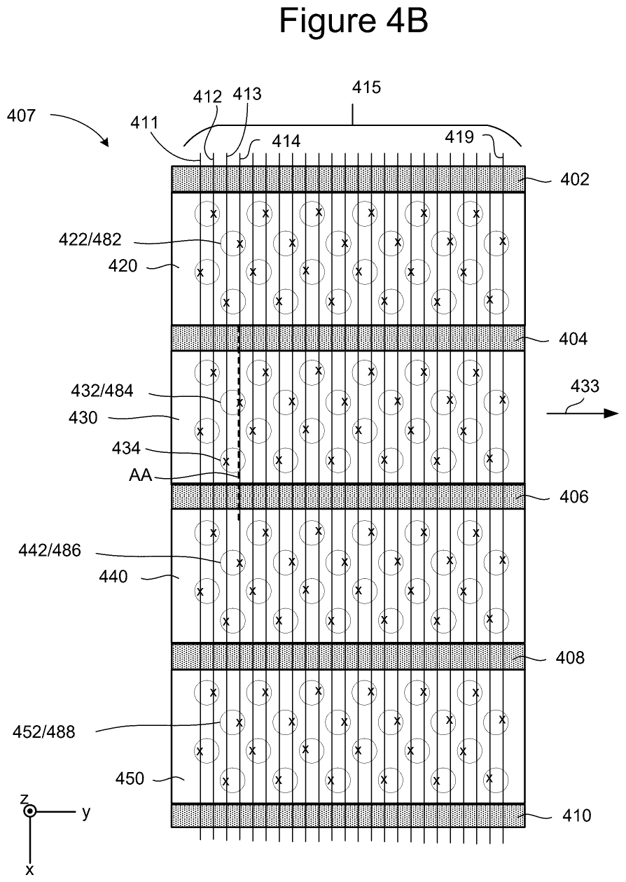

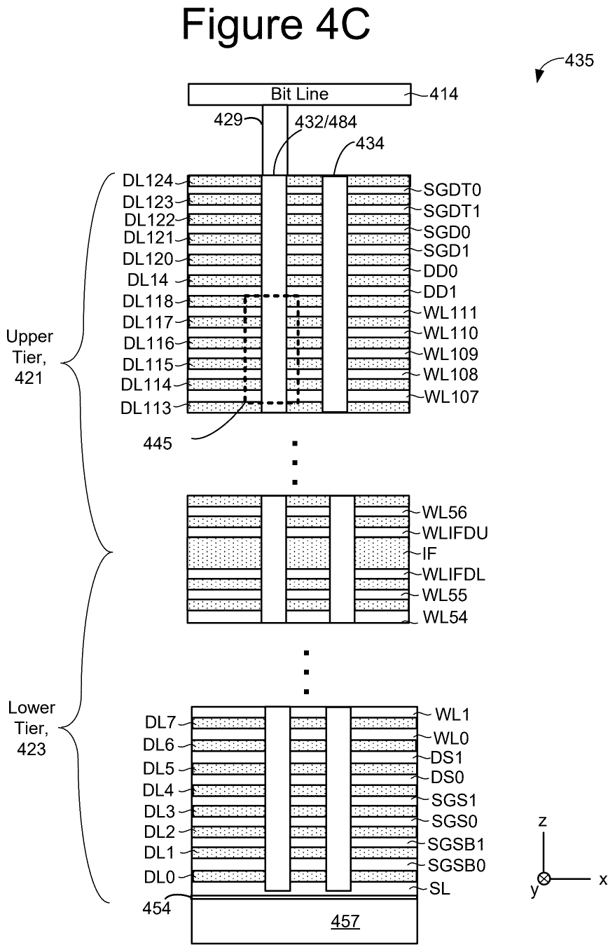

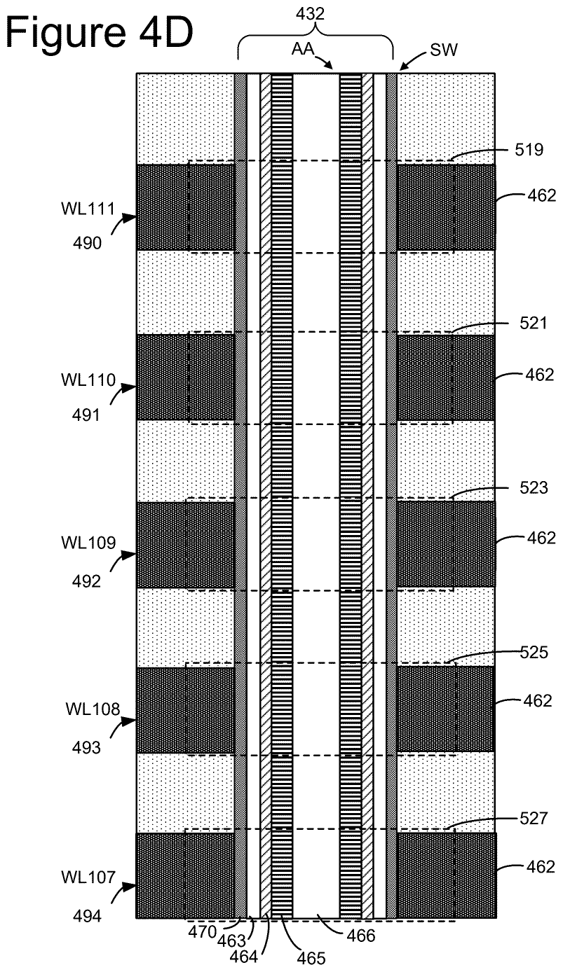

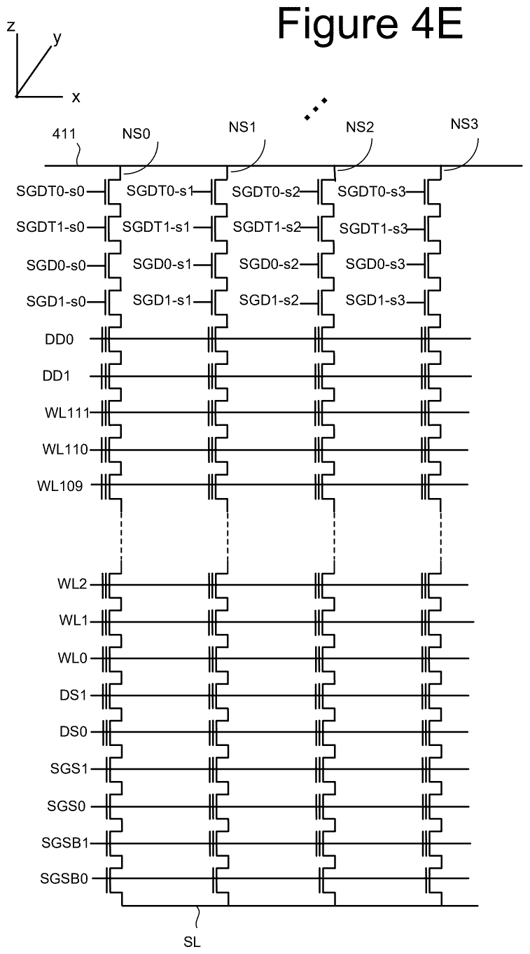

In one embodiment, the non-volatile memory 130 is NAND. The NAND memory may be in a three-dimensional memory structure or a two-dimensional memory structure. FIG. 4 s a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three-dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend downward through all of the alternating dielectric layers and conductive layers.

FIG. 4A is a block diagram explaining one example organization of memory structure 202, which is divided into four planes 403-A, 403-B, 403-C, and 403-D. Each plane 403 is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. In an embodiment, each plane 403 has a set of bit lines that extend across all of the blocks in that plane. In an embodiment, one block per plane is selected at a time. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows four planes 403-A, 403-B, 403-C, and 403-D more or fewer than two planes can be implemented. In some embodiments, memory structure 202 includes four planes. In some embodiments, memory structure 202 includes eight planes. In some embodiments, read can be performed in parallel in a first selected block in plane 403-A, a second selected block in plane 403-B, a third selected block in plane 403-C, and a fourth selected block in plane 403-D.

FIGS. 4B-4E depict an example three dimensional (“3D”) NAND structure that corresponds to the structure of FIG. 4 and can be used to implement memory structure 202 of FIGS. 2A and 2B. FIG. 4B is a diagram depicting a top view of a portion 407 of Block 2. As can be seen from FIG. 4B, the physical block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, and 452. Vertical column 422 implements NAND string 482. Vertical column 432 implements NAND string 484. Vertical column 442 implements NAND string 486. Vertical column 452 implements NAND string 488. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the physical block is depicted. It is contemplated that more than twenty-four bit lines connected to vertical columns of the physical block. Each of the circles representing vertical columns has an “x” to indicate its connection to one bit line. For example, bit line 414 is connected to vertical columns 422, 432, 442 and 452.

The physical block depicted in FIG. 4B includes a set of isolation regions 402, 404, 406, 408, and 410, which are formed of SiO₂; however, other dielectric materials can also be used. Isolation regions 402, 404, 406, 408, and 410 serve to divide the top layers of the physical block into four regions; for example, the top layer depicted in FIG. 4B is divided into regions 420, 430, 440, and 450, which are referred to herein as “sub-blocks. Each sub-block contains a large number of NAND strings. In one embodiment, isolation regions 402 and 410 separate the physical block 407 from adjacent physical blocks. Thus, isolation regions 402 and 410 may extend down to the substrate. In one embodiment, the isolation regions 404, 406, and 408 only divide the layers used to implement select gates so that NAND strings in different sub-blocks can be independently selected. Referring back to FIG. 4, the IR region may correspond to any of isolation regions 404, 406, or 408. In one example implementation, a bit line only connects to one vertical column/NAND string in each of regions (sub-blocks) 420, 430, 440, and 450. In that implementation, each physical block has sixteen rows of active columns and each bit line connects to four NAND strings in each block. In one embodiment, all of the four vertical columns/NAND strings connected to a common bit line are connected to the same word line (or set of word lines); therefore, the system uses the drain side selection lines to choose one (or another subset) of the four to be subjected to a memory operation (program, verify, read, and/or erase).

Although FIG. 4B shows each region (420, 430, 440, 450) having four rows of vertical columns, four regions (420, 430, 440, 450) and sixteen rows of vertical columns in a block, those exact numbers are an example implementation. Other embodiments may include more or fewer regions (420, 430, 440, 450) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1, SGS0, and SGS1. The SGS layers may have more or fewer than four layers. Six dummy word line layers DD0, DD1, WLIFDU, WLIDDL, DS1, and DS0 are provided, in addition to the data word line layers WL0-WL111. There may be more or fewer than 112 data word line layers and more or fewer than six dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 414. NAND string 484 has a source-end at a bottom of the stack and a drain-end at a top of the stack. The source end is connected to the source line SL. A conductive via 429 connects the drain-end of NAND string 484 to the bit line 414.

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have the same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

FIG. 4C depicts an example of a stack 435 having two tiers (lower tier 423, upper tier 421). A two tier or other multi-tier stack can be used to form a relatively tall stack while maintaining a relatively narrow memory hole width (or diameter). After the layers of the lower tier are formed, memory hole portions are formed in the lower tier. Subsequently, after the layers of the upper tier are formed, memory hole portions are formed in the upper tier, aligned with the memory hole portions in the lower tier to form continuous memory holes from the bottom to the top of the stack. The resulting memory hole is narrower than would be the case if the hole were etched from the top to the bottom of the stack rather than in each tier individually. An interface (IF) region is created where the two tiers are connected. The IF region is typically thicker than the other dielectric layers. Due to the presence of the IF region, the adjacent word line layers suffer from edge effects such as difficulty in programming or erasing. These adjacent word line layers can therefore be set as dummy word lines (WLIFDL, WLIFDU). In some embodiments, the tiers are erased independent of one another. Hence, data may be maintained in the upper tier 421 after the lower tier 423 is erased. Likewise, data may be maintained in the lower tier 423 after upper tier 421 is erased.

FIG. 4D depicts a view of region 445 of FIG. 4C. Data memory cell transistors 519, 521, 523, 525, and 527 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vt of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4E is a schematic diagram of a portion of the memory array 202. FIG. 4E shows physical data word lines WL0-WL111 running in the x-direction. The physical data word lines WL0-WL111 may also extend in the y-direction across the entire extent of the block. Therefore, each word line connects to many more NAND strings in the block. The structure of FIG. 4E corresponds to a portion 407 in Block 2 of FIG. 4A, including bit line 411. Within the physical block, in one embodiment, each bit line is connected to four NAND strings. Thus, FIG. 4E shows bit line 411 connected to NAND string NS0, NAND string NS1, NAND string NS2, and NAND string NS3.

In one embodiment, there are four sets of drain side select lines in the physical block. For example, the set of drain side select lines connected to NS0 include SGDT0-s0, SGDT1-s0, SGD0-s0, and SGD1-s0. Each of these drain side select lines SGDT0-s0, SGDT1-s0, SGD0-s0, and SGD1-s0 extends in the y-direction across the entire extent of the block such that each drain side select line connects to many NAND strings in the block. The set of drain side select lines connected to NS1 include SGDT0-s1, SGDT1-s1, SGD0-s1, and SGD1-s1. The set of drain side select lines connected to NS2 include SGDT0-s2, SGDT1-s2, SGD0-s2, and SGD1-s2. The set of drain side select lines connected to NS3 include SGDT0-s3, SGDT1-s3, SGD0-s3, and SGD1-s3. Herein the term “SGD” may be used as a general term to refer to any one or more of the lines in a set of drain side select lines. In some embodiments, the same operating voltage is applied to SGDT0 and SGDT1. In some embodiments, the same operating voltage is applied to SGD0 and SGD1. In some erase embodiments, different operating voltage are applied to SGDT0/SGDT1 than to SGD0/SGD1. Note that SGDT0/SGDT1 are adjacent to the bit line. In some erase embodiments, a voltage applied to SGDT0/SGDT1 in combination with a bit line voltage may be used to generate a gate induced gate leakage (GIDL) current. Such a voltage applied to SGDT0/SGDT1 may be referred to herein as a GIDL voltage.

In an embodiment, each line in a given set may be operated independent from the other lines in that set to allow for different voltages to the gates of the four drain side select transistors on the NAND string. Moreover, each set of drain side select lines can be selected independent of the other sets. Each set drain side select lines connects to a group of NAND strings in the block. Only one NAND string of each group is depicted in FIG. 4E. These four sets of drain side select lines correspond to four “sub-blocks.” A first sub-block corresponds to those vertical NAND strings controlled by SGDT0-s0, SGDT1-s0, SGD0-s0, and SGD1-s0. A second sub-block corresponds to those vertical NAND strings controlled by SGDT0-s1, SGDT1-s1, SGD0-s1, and SGD1-s1. A third sub-block corresponds to those vertical NAND strings controlled by SGDT0-s2, SGDT1-s2, SGD0-s2, and SGD1-s2. A fourth sub-block corresponds to those vertical NAND strings controlled by SGDT0-s3, SGDT1-s3, SGD0-s3, and SGD1-s3. As noted, FIG. 4E only shows the NAND strings connected to bit line 411. However, a full schematic of the block would show every bit line and four vertical NAND strings connected to each bit line.

The storage systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate.

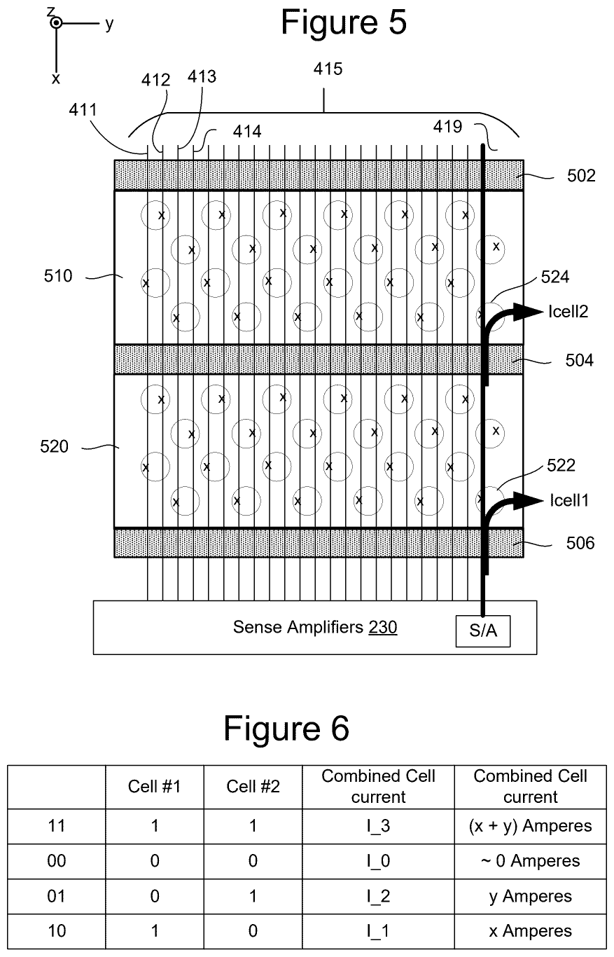

FIG. 5 is a diagram depicting an embodiment of a system that senses combined currents of memory cells on different NAND strings. The system is able to determine a bit value for each memory cell based on a magnitude of the combined current. This sensing technique allows two memory cells to be sensed in very close to the same time a single memory cell could be sensed, thereby essentially doubling the read bandwidth. The diagram depicts a top view of a portion of a memory structure 202. Two sub-blocks 510, 520 are depicted. These two sub-blocks 510, 520 could be in the same block or adjacent blocks. Isolation regions 502, 504, 506 serve to divide the top layers into the two sub-blocks 510, 520. If an isolation region separates two sub-blocks into adjacent physical blocks then the isolation region may extend down to the substrate. However, if the isolation region does not separate two sub-blocks into adjacent physical blocks then the isolation region is not required to extend down to the substrate (see, for example, IR region in FIG. 4). For ease of discussion the bit lines 415 from FIG. 4B are again shown in FIG. 5. Note that the bit lines 415 extend across many blocks in a plane.

FIG. 5 shows an example in which a first memory cell (Cell1) on NAND string 522 in sub-block 520 and second memory cell on NAND string 524 in sub-block 510 are being sensed by a sense amplifier (S/A). The cell currents are referred to as Icell1 and Icell2, respectively. The SGD transistors of both NAND string 522 and NAND string 524 are turned on the connect the channel of NAND string 522 and the channel of NAND string 524 to the same bit line. The memory system applies a reference voltage to the control gate of first memory cell and to the control gate of the second memory cell, while applying pass voltages to unselected memory cells on the NAND strings 522, 524. Therefore, the bit line current will be the sum of the two memory cell currents. Thus, the S/A senses the combined currents Icell1+Icell2.

At the same time other sense amplifiers may sense other pairs of memory cells. In this example, each pair of memory cells has a first memory cell in a first sub-block and a second memory cell in a second sub-block. These two sub-blocks may be in the same block or different blocks. When in different blocks the two blocks may be adjacent to each other, but are not required to be adjacent to one another. The two NAND strings that contain the two memory cells being sensed by the same S/A are connected to the same bit line.

FIG. 6 is a table depicting a mapping between combined currents a bit values for an embodiment of sensing pairs of memory cells together. Each memory cell is programmed to store one bit in this example. The memory cells are programmed to current states, where a current state is defined by the magnitude of the cell current for a pre-defined Vgs. That is, the same magnitude is used for Vgs regardless of the current state. The two memory cells are programmed such that there are four possible target magnitudes for the combined currents from the two cells. In FIG. 6 these four possible target current magnitudes are referred to as I_0, I_1, I_2, and I_3. For purpose of discussion, the current magnitudes are ordered smallest to largest as follows: I_0<I_1<I_2<I_3. The sense amplifier is able to demarcate between these four current magnitudes in order to determine the bit value for each cell. In an embodiment, the current for I_0 is 0 Amperes or very close to 0 Amperes, the current for I_1 is x Amperes, the current for I_2 is y Amperes, and the current for I_3 is (x+y) Amperes. As an example, x Amperes could be about 90 nA and y Amperes could be about 155 nA; however, other values may be used.

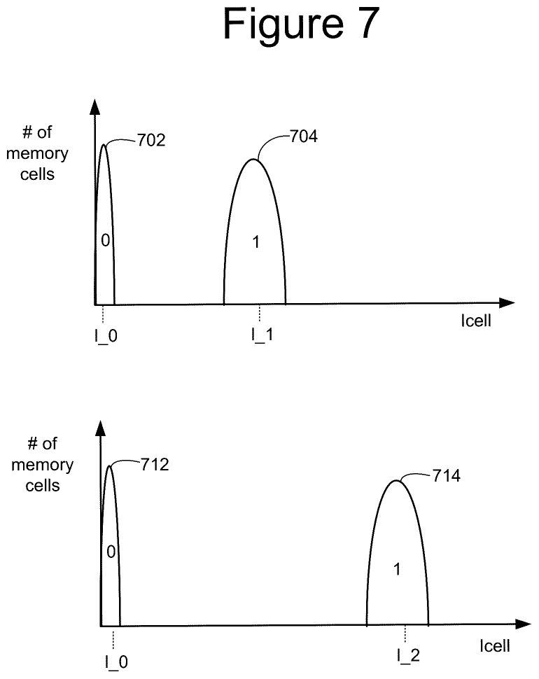

FIG. 7 depicts current (Icell) distributions for an embodiment of programming memory cells for double bandwidth read. Current distributions 702 and 704 are for a first group of memory cells that may be in a first sub-block such as, for example, sub-block 510. Current distributions 712 and 714 are for a second group of memory cells that may be in a second sub-block such as, for example, sub-block 520. Current distribution 702 corresponds to a bit value of “0”, whereas current distribution 704 corresponds to a bit value of “1”. Current distribution 712 corresponds to a bit value of “0”, whereas current distribution 714 corresponds to a bit value of “1”. Current distributions 702 and 712 are each associated with a target current of I_0. Current distributions 702 and 712 may be referred to “non-conducting” current states, by which it is meant the memory cell current will be very close to zero when the pre-defined read reference voltage is applied to the memory cell. Current distribution 704 is associated with a target current of I_1. Current distribution 714 is associated with a target current of I_2 Current distributions 704 and 714 may be referred to “conducting” current states, by which it is meant the memory cell current will conduct a significant current that changes the voltage of a sense node by a detectable amount when the pre-defined read reference voltage is applied to the memory cell. Note that memory cells in current distribution 714 have a significantly higher current than memory cells in current distribution 704. Also note that although memory cells in current distribution 704 may have about the same current as memory cells in current distribution 702, the system is able to determine the correct bit value for each cell as will be explained below. Briefly, when sensing the combined current in a pair of memory cells there are four possible combined currents: I_0+I_0, I_0+I_1, I_0+I_2, or I_1+I_2. For purpose of illustration, if it is assumed that I_0 is 0, then the four possible combined currents are I1, I1, I2, and I3 (where I3 is I1+I2). These four possible currents are listed in the table of FIG. 6. Moreover, current distributions in FIG. 7 may be used to encode the bit values in the table in FIG. 6.

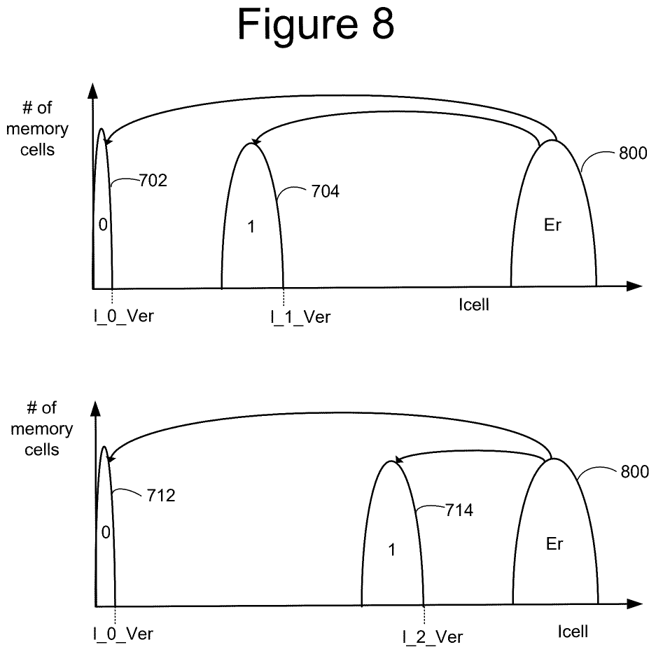

FIG. 8 depicts how programming of memory cells is performed in an embodiment. Note that both the x-axis and the y-axis may be on a logarithmic scale. The memory cells are first erased to a low threshold voltage, which corresponds to a high current with the assumption of using the same Vgs for all current measurements. A verify current is depicted for each current distribution. Memory cells in the first group that are to store a “0” are programmed from the erase state (Er) 800 to a verify current of I_0_Ver, thereby ending up in current distribution 702. Memory cells in the first group that are to store a “1” are programmed from the erase state to a verify current of I_1_Ver, thereby ending up in current destination 704. Memory cells in the second group that are to store a “0” are programmed from the erase state to a verify current of I_0_Ver, thereby ending up in current destination 712. Memory cells in the second group that are to store a “1” are programmed from the erase state 800 to a verify current of I_2_Ver, thereby ending up in current destination 714. In this example, memory cells in both groups that are to store a “0” are programmed to the same target verify current (I_0_Ver). However, memory cells to store a “1” are programmed to different target verify currents, depending on their group assignment. Note that the programming may involve applying many program pulses with small program voltage step sizes to achieve narrow current distributions.

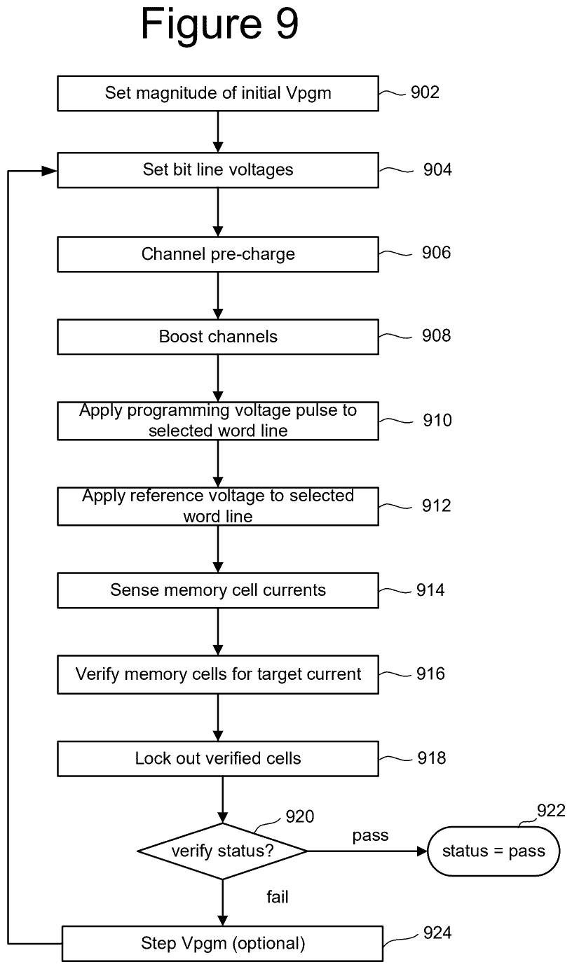

FIG. 9 is a flowchart of one embodiment of programming process for programming current states. The process includes multiple loops, each of which includes a program phase and a verify phase. In an embodiment, the process is used to program weights of an AI model into the memory cells. In some techniques, the memory system determines a target current to which a memory cell transistor should be programmed, with an assumption of a particular voltage to be applied to the memory cell transistor to cause the memory cell current. For example, when programming weights of a neural network model, the memory system may determine a target current for a memory cell transistor (e.g., NAND memory cell).

In one example embodiment, the process in FIG. 9 is performed for memory structure 202 using the one or more control circuits (e.g., system control logic 260, column control circuitry 210, row control circuitry 220) discussed above. Typically, the program voltage applied to the control gates (via a selected data word line) during a program operation is applied as a series of program pulses (e.g., voltage pulses). Between programming pulses are a set of one or more verify pulses (e.g., voltage pulses) to perform verification. In many implementations, the magnitude of the program pulses is increased with each successive pulse by a predetermined step size. In step 902 of FIG. 9, the programming voltage signal (Vpgm) is initialized to the starting magnitude (e.g., −12-16V or another suitable level). Optionally a program counter PC may be maintained by state machine 262 and initialized at 1. In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. Additionally, as memory cells reach their intended target state, they will be inhibited from further programming. Those NAND strings (e.g., unselected NAND strings) that include memory cells connected to the selected word line that are to be inhibited from programming have their channels boosted to inhibit programming. In step 904 the bit line voltage is established. The magnitude of the bit line voltage is used to either enable programming of a memory cell connected to the selected word line or to inhibit programming of a memory cell connected to the selected word line. If a bit line receives a program inhibit voltage the NAND channel connected to the bit line is boosted by voltages applied to unselected word lines. When a channel has a boosted voltage, the voltage differential between the channel and the word line is not large enough to cause programming. To assist in the boosting, in step 906 the system will pre-charge channels of NAND strings that include memory cells connected to the selected word line that are to be inhibited from programming. In step 908, NAND strings that include memory cells connected to the selected word line that are to be inhibited from programming have their channels boosted to inhibit programming. Such NAND strings are referred to herein as “unselected NAND strings.” In one embodiment, at least some unselected word lines receive one or more boosting voltages (e.g., ~7-11 volts) to perform boosting schemes. A program inhibit voltage is applied to the bit lines coupled the unselected NAND string.

In step 910, a program voltage pulse of the programming voltage signal Vpgm is applied to the selected word line (the word line selected for programming). If a memory cell on a NAND string should be programmed, then the corresponding bit line is biased at a program enable voltage. In step 910, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all of the memory cells connected to the selected word line will concurrently have their threshold voltage change, unless they are inhibited from programming.

In step 912 a reference voltage is applied to the selected word line. To program the memory cell to target currents the same reference voltage may be used for all current states. Read pass voltages may be applied to unselected word lines. The read pass voltage has a magnitude at least as high as the highest Vt of any of the memory cells. Also, the voltages on the bit lines is set to a suitable voltage for sensing the memory cells.

In step 914, memory cell currents are sensed via the respective bit lines. In this sensing step, only a single NAND string is connected to a bit line. Thus, each sense amplifier will be testing the cell current of a single memory cell. In an embodiment, the memory cell current is applied to a sense node such as a sense capacitor. The memory cell current may be applied to the sense node for a specific period of time referred to as a sense time (also referred to as an “integration time”). The sense node may be pre-charged to an initial voltage prior to discharging the sense node with the memory cell current for the sense time. In an embodiment, step 914 is testing for one of three possible verify current magnitudes (e.g., I_0_Ver, I_1_Ver, or I_2_Ver). In an embodiment, the sense amplifier uses a single sense capacitor but three different sense times to test for the three possible verify current magnitudes. In an embodiment, the sense amplifier uses three sense capacitors having different capacitances (with the same sense time) to test for the three possible verify current magnitudes.

Step 916 includes a determination, for each cell being programmed, of whether the respective memory cell has reached its target verify current. The voltage on the sense node may be tested after the sense time to determine whether the memory cell has reached the target verify current.

In step 918, a memory cell may be locked out after the memory cell has been verified that the memory cell has reached its target verify current. In an embodiment, when programming memory cells to currents to represent values such as weights a memory cell may be locked out when it reaches the target verify current for a verify reference voltage applied to the selected word line.

If, in step 918, it is determined that all of the memory cells have reached their target states (pass), the programming process is complete and successful because all selected memory cells were programmed and verified to their target states. A status of “PASS” is reported in step 922. Otherwise if, in step 920, it is determined that not all of the memory cells have reached their target states (fail), then the programming process continues to step 924. At step 924 the programming voltage signal Vpgm is optionally stepped up to the next magnitude. For example, the next pulse may have a magnitude greater than the previous pulse by a step size ΔVpgm (e.g., a step size of 0.1-1.0 volts). After step 924, the process loops back to step 904 to establish bit values to either enable or inhibit programming so that another iteration (steps 904-918) of the programming process of FIG. 9 is performed.

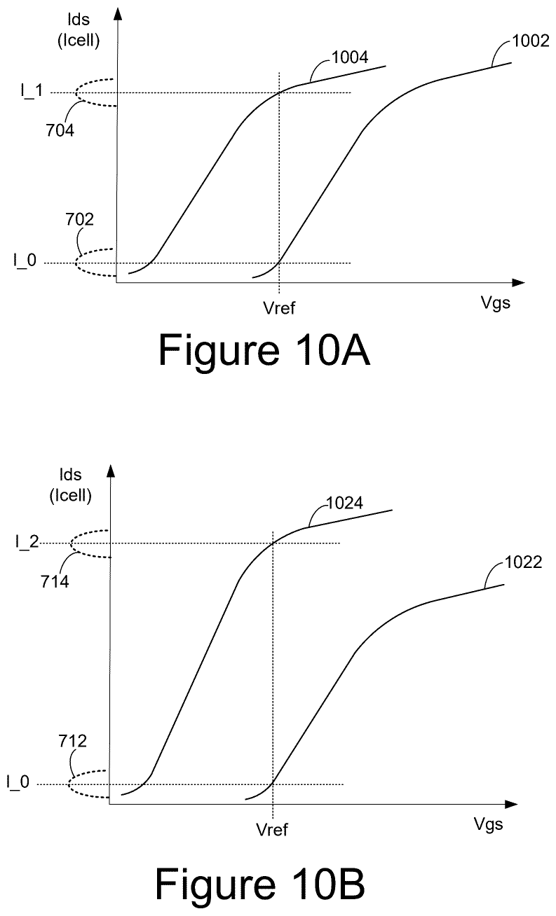

FIG. 10A depicts cell current versus Vgs for a first group of memory cells that are programmed to either current distribution 702 or 704 (see FIG. 7). Plot 1002 is for memory cells programmed to current distribution 702. Plot 1004 is for memory cells programmed to current distribution 704. For each case the memory cell current will depend on Vgs, which is the voltage between the selected word line and the source line. The voltage Vref depicted on the Vgs axis is for purpose of an example voltage applied as Vgs. Note that the intersection of Vref with plot 1002 occurs at a current of I_0. Note that the intersection of Vref with plot 1004 occurs at a current of I_1. The current distributions 702, 704 shown on the Ids axis represent that the memory cells may have some small deviation from the target currents.

FIG. 10B depicts cell current versus Vgs for a second group of memory cells that are programmed to either current distribution 712 or 714 (see FIG. 7). Plot 1002 is for memory cells programmed to current distribution 702. Plot 1022 is for memory cells programmed to current distribution 712. For each case the memory cell current will depend on Vgs. For consistency, the Vref in FIG. 10B is the same as Vref in FIG. 10A. Note that the intersection of Vref with plot 1022 occurs at a current of I_0. Note that the intersection of Vref with plot 1024 occurs at a current of I_2. The magnitude of I_2 is greater than the magnitude of I_1. The current distributions 712, 714 shown on the Ids axis represent that the memory cells may have some small deviation from the target currents.

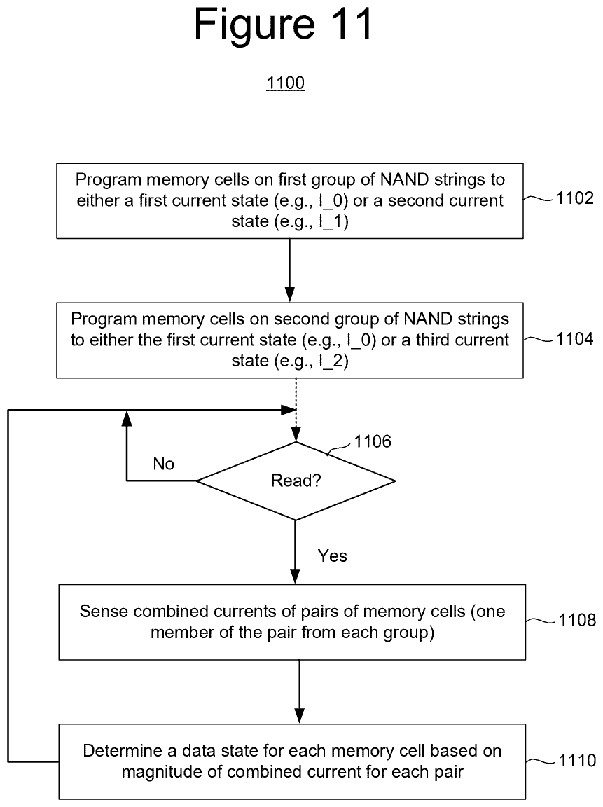

FIG. 11 is a flowchart of one embodiment of a process 1100 of operating flash memory for double bandwidth during read. The process 1100 will be described in connection with a first group of memory cells and a second group of memory cells. Pairs of memory cells are read together with each pair having a first memory cell in the first group and a second memory cell in the second group. The first group of memory cells are on a first group of NAND strings connected to a set of bit lines and the second group of memory cells are on a second group of NAND strings connected to the set of bit lines. Each pair of memory cells is associated with the same bit line, such that the bit line can be used to sense a combined current from the pair.

Step 1102 includes programming memory cells on the first group of NAND strings to either a first current state or a second current state. The choice of the current state depends on whether the memory cell is to store a “1” or a “0”. For the sake of discussion, each memory cell on the first group is programmed to either current distribution 702 or 704 (see FIG. 8). The process in FIG. 9 may be used for this programming. For the sake of illustration memory cells connected to the selected word line in sub-block 510 are programmed in step 1102. Step 1102 may include programming memory cells on the first group of NAND strings to either a non-conducting current state to represent a first bit value or a first conducting state having a first current magnitude to represent a second bit value.

Step 1104 includes programming memory cells on the second group of NAND strings to either the first current state or a third current state. The choice of the current state depends on whether the memory cell is to store a “1” or a “0”. For the sake of discussion, each memory cell on the second group is programmed to either current distribution 712 or 714 (see FIG. 8). The process in FIG. 9 may be used for this programming. For the sake of illustration memory cells connected to the selected word line in sub-block 520 are programmed in step 1104. Step 1104 may include programming memory cells on the second group of NAND strings to either the non-conducting current state to represent the first bit value or a second conducting state having a second current magnitude to represent the second bit value.

In an example scenario the memory cells are programmed once and then read many times. For example, for AI inferencing, the weights are programmed once and read many times during the inference stage. A dashed line between step 1104 and 1106 indicates a possible gap between the programming and reading. When the memory cells are to be read (step 1106 is yes) then steps 1108 and 1110 are performed. These reading steps (1108 and 1110) may be performed many times with the programming done once.

Step 1108 includes sensing the combined currents of pairs of memory cells. Each pair has one member in the first group and one member in the second group. Step 1108 includes, for a particular pair, sensing a current in a bit line. The bit line current has the combined current of the two memory cells of that pair. Step 1108 may include, for each pair of memory cells to be sensed together, connecting a first channel of a first NAND string having a first memory cell in the pair to a bit line while connecting a second channel of a second NAND string having a second memory cell in the pair to the bit line while and while applying a reference voltage to the first memory cell in the pair and the second memory cell in the pair. The, a sense amplifier senses the bit line current, which has the combined cell current of the first memory cell and the second memory cell.

Step 1110 includes determining a data state for each memory cell based on a magnitude of the combined current for each pair. Step 1110 includes, for a particular pair, determining a first bit value for the first member of the pair and a second bit value for the second member of the pair. These two bit values may be determined by demarcating between four possible combined currents. For example, with reference to FIG. 6, the sense amplifier connected to the bit line may demarcate between I_0, I_1, I_2, and I_3. Step 1110 may include determine a first bit value for the first memory cell of the pair by determining whether the magnitude of the combined current is above or below a first current, determining a second current to test for based on the first bit value, and determining a second bit value for the second memory cell of the pair by determining whether the magnitude of the combined current is above or below the second current.

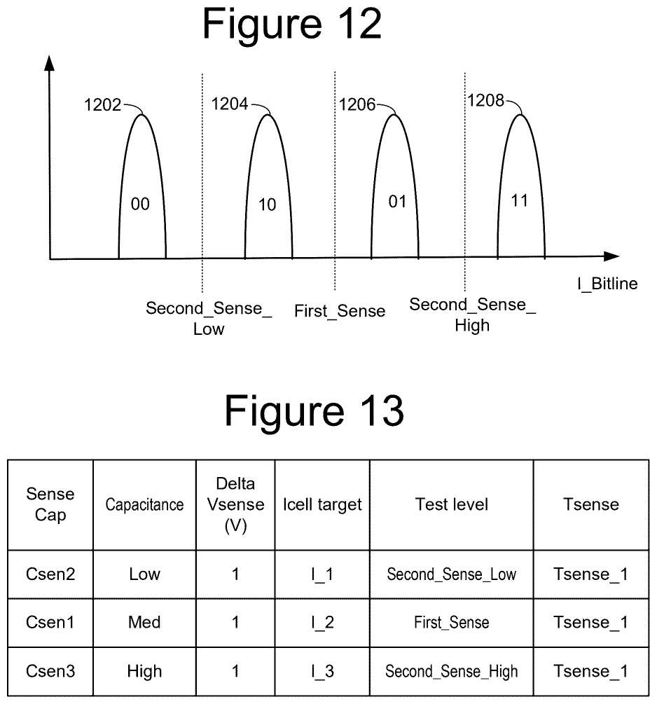

FIG. 12 shows example current distributions for combined currents of two memory cells being sensed together. There are four current distributions 1202, 1204, 1206, 1208. Current distribution 1202 corresponds to data state “00”. Current distribution 1204 corresponds to data state “10”. Current distribution 1206 corresponds to data state “01”. Current distribution 1208 corresponds to data state “11”. This is just one possible coding for the current distributions.

Three current reference levels are depicted to distinguish between the current distributions. In an embodiment, the sense amplifier 325 is able to test for all three current reference levels. However, when sensing a pair of memory cells, the sense amplifier 325 only needs to test for two of the three reference levels. An embodiment of a sense amplifier 325 performs a first test for the level “First_Sense”. The result of testing at “First_Sense” indicates the bit value in one of the two memory cells. Specifically, if the magnitude of the bit line current is above “First Sense” then the data state is either “01” or “11”. Alternatively, if the magnitude of the bit line current is below “First Sense” then the data state is either “00” or “10”. Therefore, the first sense indicates whether the first memory cell being tested has a bit value of 0 or 1.

The sense amplifier only needs to test at one of the other two current levels to determine the bit value for the other memory cell. If the first sense revealed a bit value of “0” for the first memory cell, then the sense amplifier tests for “Second_Sense_Low”. The result of test at Second_Sense_Low indicates whether the second memory cell has a bit value of “0” or “1”. If the first sense revealed a bit value of “1” for the first memory cell, then sense amplifier tests for “Second_Sense_High”. Similarly, the result of test at Second_Sense_High indicates whether the second memory cell has a bit value of “0” or “1”.

Note that distribution 1202 may correspond to I_0, distribution 1204 may correspond to I_1, distribution 1206 may correspond to I_2, and distribution 1208 may correspond to I_3. For the sake of discussion, testing at the various current levels in FIG. 12 may be referred to as testing for a current just higher than the test level. For example, testing at Second_Sense_Low may be referred to as testing for I_1, testing at First_Sense may be referred to as testing for I_2, and testing at Second_Sense_High may be referred to as testing for I_3.

An embodiment of the sense amplifier 325 has three sense nodes to test for the three current levels. Each sense node has a different capacitance to test for one of the three current levels in order to demarcate between the four possible combined current magnitudes. FIG. 13 is a table to show example parameters for an embodiment of sense nodes in a sense amplifier 325. Three capacitors are listed as having Low, Medium, or High capacitance, which indicates the relative capacitance (i.e., Csen2<Csen1<Csen3). Csen1 is used to test for the First_Sense level, Csen2 is used to test for the Second_Sense_Low level, Csen3 is used to test for the Second_Sense_High level. The same sense time (Tsense_1) will be used for all three sense capacitors. The following Equations may be used to determine suitable values for the parameters.

$$Csen \times Δ Vsen = ixtime \qquad ( 1 )$$

$$time = Csen \times \frac{Δ Vsen}{i} \qquad ( 2 )$$

In the table of FIG. 13, the Delta Vsense of 1V refers to a 1V sense node development (e.g., discharge) due to applying the bit line current to the sense node. The 1V is an example that could be modified, but is the same for all sense nodes. An example Tsense is 200 nanoseconds. An example for Csen2 is 18 fF to test for 90 nA. An example for Csen1 31 18 fF to test for 155 nA. An example for Csen3 is 49 fF to test for 245 nA. All of these examples are for purpose of illustration and may be modified as needed.

FIG. 14 is a schematic diagram of an embodiment of a sense amplifier that may be used to sense two memory cells on different NAND strings connected to the same bit line in a single read operation. The sense amplifier 325 has three sense nodes such as in the table in FIG. 13. This read technique can essentially double the read bandwidth relative to sensing a single memory cell. The sense amplifier 325 has three sense nodes: SEN1, SEN2, SEN3. Each sense node is connected to a sense capacitor and a sense transistor. SEN1 is connected to sense capacitor Csen1 and sense transistor SEN1 tr. SEN2 is connected to sense capacitor Csen2 and sense transistor SEN2 tr. SEN3 is connected to sense capacitor Csen3 and sense transistor SEN3 tr. One of these sense nodes will be connected to the bit line at one point in time such that the relevant sense capacitor is discharged by the bit line current when sensing the memory cells. The relevant sense transistor is used to sense the voltage level on the sense capacitor after the discharge time. Each sense capacitor has a different capacitance. Based on their respective capacitances, each sense capacitor tests for a different reference current. These currents (I_1, I_2, I_3) listed in FIG. 13 may correspond to those currents in FIG. 6. As an example, I_1 may be 90 nA, I_2 may be 155 nA, and I_3 may be 245 nA. All of the capacitances, currents and the sense time are examples and may be modified to suit needs.

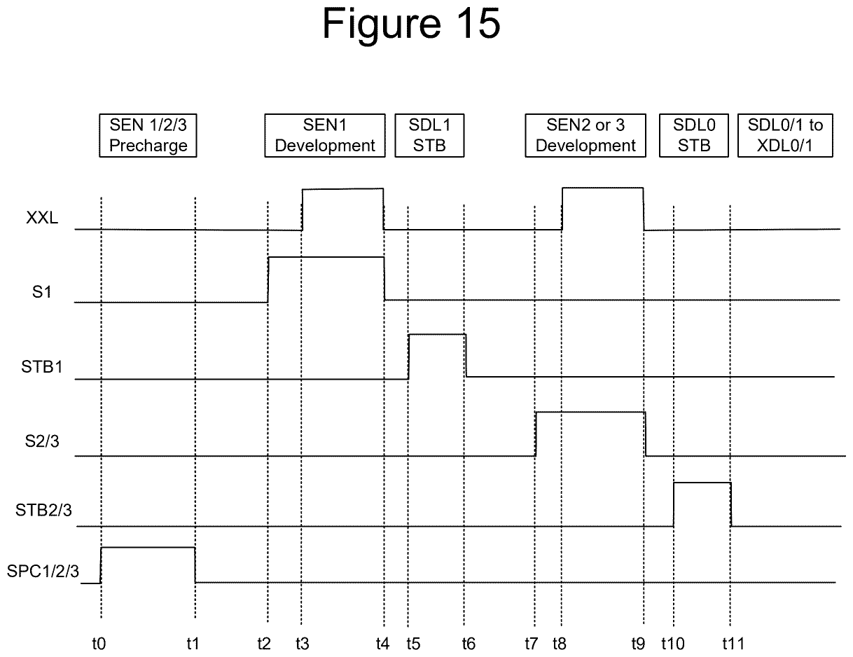

FIG. 15 is a timing diagram for various signals in the sense amplifier 325 in FIG. 14. Between t0 and t1 there is a sense node pre-charge phase, which provides an initial charge on SEN1, SEN2, and SEN3. Between t0 and t1 the signals SPC1, SPC2, and SPC3 are high to turn on transistors M5, M6, and M7. Transistors M5, M6, and M7 are each connected to a voltage VHLB, which pre-charges SEN1, SEN2, and SEN3.

Additionally, the bit line may be charged and clamped to a voltage that it suitable for sensing the memory cells. The SCOM node between XXL transistor T1 and BLC transistor M2 can be clamped by NLO transistor M3 and may behave the same as the BLC transistor M2. To charge the bit line, NLO transistor M3 is turned on (by taking NLO signal high) while the BLC transistor M2 is on (by taking BLC signal high). At this time, the BLX transistor M4 and the XXL transistor M1 are off. During sensing the BLC transistor M2 may be operated as a source follower to clamp the bit line at a sensing voltage. One condition to operate as a source-follower is for the voltage at the control gate of BLC transistor T2 to be lower than the voltage on the drain. When acting as a source-follower the bit line voltage is set or clamped at Vblc−Vth, where Vblc is the voltage on the control gate and Vth, e.g., 0.7 V, is the threshold voltage of the BLC transistor T2. This assumes the source line (SL) is at 0 V. The source line voltage is referred to herein as Vcelsrc. If Vcelsrc is non-zero, the bit line voltage is clamped at Vblc−Vcelsrc−Vth. The transistor M2 is therefore sometimes referred to as a bit line clamp (BLC) transistor, and the voltage Vblc on the control gate may be referred to as a bit line clamp voltage. The source-follower mode can be used during sensing operations such as read and verify operations.

The time between t2 and t4 is used to develop the voltage on SEN1 (SEN1 development). Between t2 and t4 S1 is high to open transistor M8, which is connected to SEN1. The sense time (t2 to t3) is controlled by the signal XXL, which is applied to the XXL transistor M1. Therefore, SEN1 is connected to the bit line by way of the XXL transistor M1 and BLC transistor M2. The bit line current will be the combined cell current of the two memory cells being sensed. The dashed arrow “MSB sensing” in FIG. 14 refers to the current pathway for sensing the bit value of one of the cells (referred to as the MSB).

The time between t5 and t6 is used for storing a result for the bit in the first memory cell of the pair. This result will be stored in the SDL1 latch. Between t5 and t6 the signal STB1 is high to turn on strobe1 transistor M9, which is connected to SEN1 tr. The sense transistor (SEN1 tr) is used to test the magnitude of the voltage on SEN1. Specifically, strobe1 transistor M9 is turned on by STB1 to test the magnitude of the voltage on SEN1. This result is then passed to SDL1. Therefore, the MSB is stored in SDL1. FIG. 16A summarizes the parameters for sensing the MSB by the sense amplifier in FIG. 14.

Next, the bit in the second memory cell of the pair is sensed by either using SEN2 or SEN3. Referring to FIG. 14 note that there are two current paths labeled second sensing. Only one of these paths will be used for a particular operation. The choice of which sense node (SEN2 or SEN3) is used depends on the bit value of the first memory cell (stored in SDL1). Logic gates 1402, 1404, 1406, 1408 are used to generate the signals S2, S3, STB2, STB3. The signals S2 and STB2 will be high (with S3 and STB3 low) if SEN2 is to be used for the second sensing. The signals S3 and STB3 will be high (with S2 and STB2 low) if SEN3 is to be used for the second sensing.

The contents of SDL1 are inverted and input to AND gate 1402. Also a signal S_2^{nd} is input to the AND gate 1402. The signal S_2^{nd} controls the timing of when the second sensing should occur. Therefore, if SDL1 is “0” and S_2^{nd} is “1”, the signal S2 (output of AND 1402) will be high. The contents of SDL1 are input to AND gate 1404, along with the signal S_2^{nd} Therefore, if SDL1 is “1” and S_2^{nd} is “1”, the signal S3 (output of AND 1404) will be high.

The contents of SDL1 are inverted and input to AND gate 1406. Also a signal STB_2^{nd} is input to the AND gate 1402. The signal STB_2^{nd} controls the timing of when the second strobe signal should occur. Therefore, if SDL1 is “0” and STB_2^{nd} is “1”, the signal STB2 (output of AND 1406) will be high. The contents of SDL1 are input to AND gate 1408, along with the signal STB_2^{nd}. Therefore, if SDL1 is “1” and STB_2^{nd} is “1”, the signal STB3 (output of AND 1408) will be high.

The time between t7 and t9 is used to develop the voltage on either SEN2 or SEN3. First the SEN2 will be discussed. Between t7 and t9 S2 is high to open transistor M10, which is connected to SEN2. The sense time (t8 to t9) is controlled by the signal XXL, which is applied to the XXL transistor M1. Therefore, SEN2 is connected to the bit line by way of the XXL transistor M1 and BLC transistor M2. The bit line current will be the combined cell current of the two memory cells being sensed. The dashed arrow “second sensing” through M10 in FIG. 14 refers to the current pathway for sensing the bit in the second memory cell. The time between t10 and t11 is used for storing a bit value for the second memory cell. This result will be stored in the SDL0 latch. Between t10 and t11 the signal STB2 is high to turn on strobe2 transistor M11, which is connected to SEN2 tr. The sense transistor (SEN2 tr) is used to test the magnitude of the voltage on SEN2. Specifically, strobe2 transistor M11 is turned on by STB2 to test the magnitude of the voltage on SEN2. This result is then passed to SDL0. Therefore, the LSB is stored in SDL0 for the example of using SEN2.

Next, using SEN3 for the second sensing will be discussed. Between t7 and t9 S3 is high to open transistor M12, which is connected to SEN3. The sense time (t8 to t9) is controlled by the signal XXL, which is applied to the XXL transistor M1. Therefore, SEN3 is connected to the bit line by way of the XXL transistor M1 and BLC transistor M2. The bit line current will be the combined cell current of the two memory cells being sensed. The dashed arrow “second sensing” through M12 in FIG. 14 refers to the current pathway for sensing the bit value in the second memory cell. The time between t10 and t11 is used for storing a result for the bit value in the second memory cell. This result will be stored in the SDL0 latch. Between t10 and t11 the signal STB3 is high to turn on strobe3 transistor M13, which is connected to SEN3 tr. The sense transistor (SEN3 tr) is used to test the magnitude of the voltage on SEN3. Specifically, strobe3 transistor M13 is turned on by STB3 to test the magnitude of the voltage on SEN3. This result is then passed to SDL0. Therefore, the bit value in the second memory cell is stored in SDL0 for the example of using SEN3. FIG. 16B summarizes the parameters for the second sensing by the sense amplifier in FIG. 14. Referring again to FIG. 15, the bit value in SDL0 is transferred to XDL0 and the bit value in SDL1 is transferred to XDL1 to complete the sensing process. Transistors M14 and M15 may be used in the bit transfers, using signals DSW1 and DSW2, respectively. Briefly, another feature of the sense amplifier 325 is to charge the bit line to a suitable voltage to either enable programming or inhibit programming. Transistors M16 and M17 may be used to pass either SRCGND (to enable programming) or VHSA (to inhibit programming).

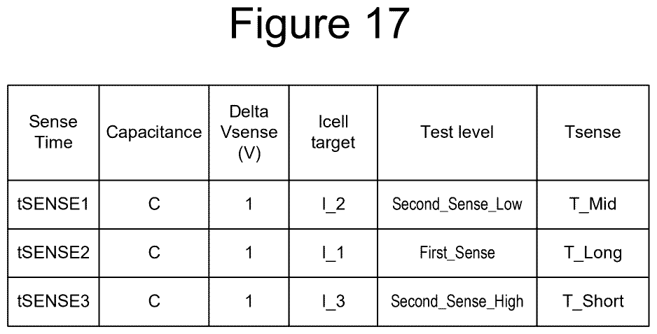

An embodiment of the sense amplifier 325 has a single sense node with three difference sense times to test for three current levels (e.g., Second_Sense_Low, First_Sense level and Second_Sense_High in FIG. 12). The three difference sense times test for one of the three current levels in order to demarcate between the four possible combined current magnitudes. FIG. 17 is a table to show example parameters for an embodiment of sense nodes in a sense amplifier 325. Three sense times are listed as having T_Mid, T_Long, and T_Short, which indicates the relative sense times (i.e., T_Short<T_Mid<T_Long). T_Mid is used to test for the First_Sense level, T_Long is used to test for the Second_Sense_Low level, T_Short is used to test for the Second_Sense_High level. The same capacitance C will be used for all three sense times. Equations 1 and 2 above may be used to determine suitable values for the parameters.

In table 17, the Delta Vsense of 1V refers to a 1V sense node development due to applying the bit line current to the sense node. The 1V is an example that could be modified, but is the same for all sense nodes. Non-limiting examples are: 31 fF for the capacitance of the sense node; T_Short of 127 ns, T_Mid of 200 ns, T_Long of 344 ns; I_3 of 245 nA, I_2 of 155 nA, I_1 of 90 nA. All of these examples are for purpose of illustration and may be modified as needed.

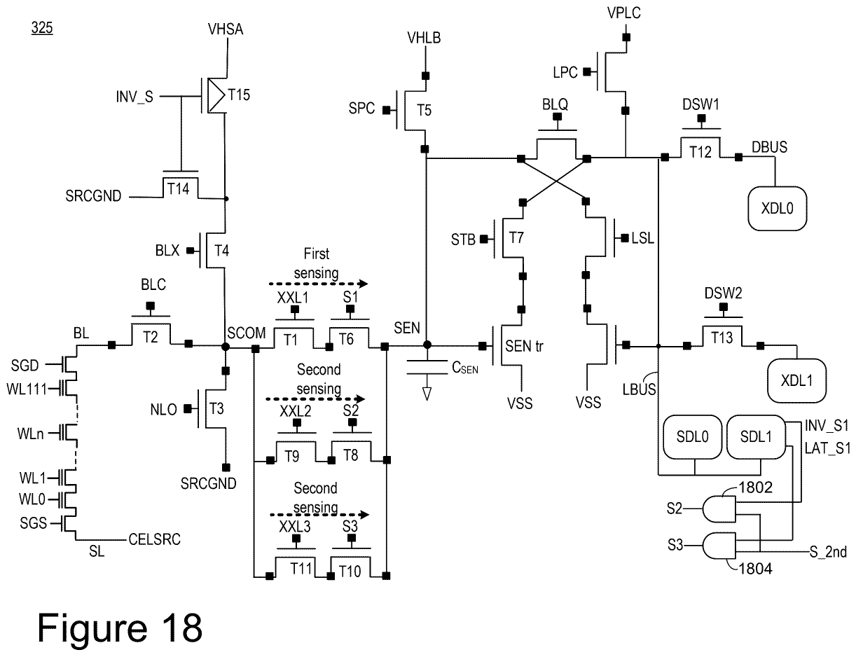

FIG. 18 is a schematic diagram of an embodiment of a sense amplifier that may be used to sense two memory cells on different NAND strings connected to the same bit line in a single read operation. This read technique can essentially double the read bandwidth relative to sensing a single memory cell. The sense amplifier 325 uses three different sense times with a single sense node, such as in the table in FIG. 17.

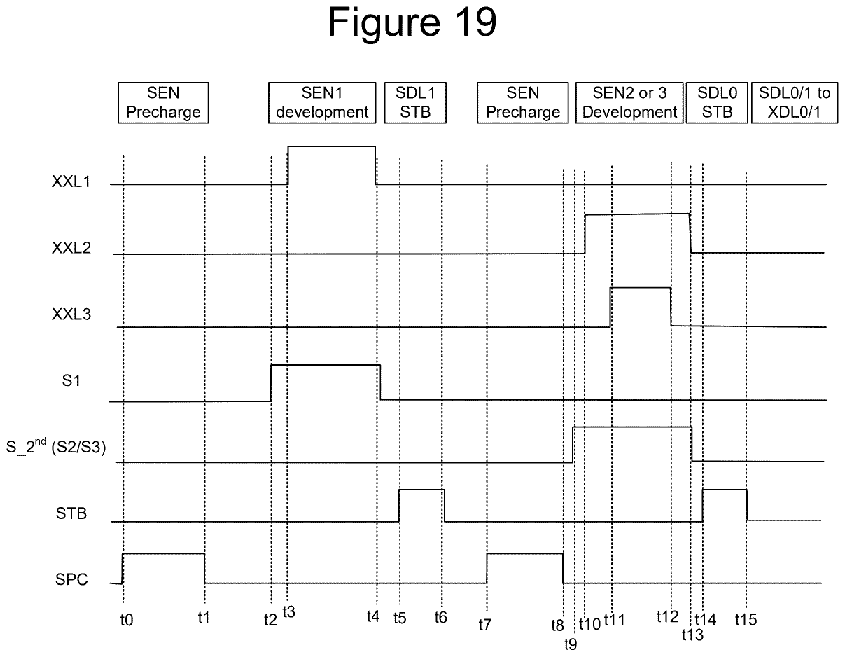

FIG. 19 is a timing diagram for various signals in the sense amplifier 325 in FIG. 18. Between t0 and t1 there is a sense node pre-charge phase, which provides an initial charge on SEN. Between t0 and t1 the signal SPC is high to turn on transistor T5. Transistor T5 is connected to a voltage VHLB, which pre-charges SEN. Additionally, the bit line may be charged and clamped to a voltage that is suitable for sensing the memory cells. The SCOM node between XXL transistor M1 and BLC transistor T2 can be clamped by NLO transistor T3 and may behave the same as the BLC transistor T2. To charge the bit line, NLO transistor T3 is turned on (by taking NLO signal high) while the BLC transistor T2 is on (by taking BLC signal high). At this time, the BLX transistor M4 and the XXL transistor T1 are off. During sensing the BLC transistor T2 may be operated as a source follower to clamp the bit line at a sensing voltage. One condition to operate as a source-follower is for the voltage at the control gate of BLC transistor T2 to be lower than the voltage on the drain. When acting as a source-follower the bit line voltage is set or clamped at Vblc−Vth, where Vblc is the voltage on the control gate and Vth, e.g., 0.7 V, is the threshold voltage of the BLC transistor M2. This assumes the source line (SL) is at 0 V. The source line voltage is referred to herein as Vcelsrc. If Vcelsrc is non-zero, the bit line voltage is clamped at Vblc−Vcelsrc−Vth. The transistor T2 is therefore sometimes referred to as a bit line clamp (BLC) transistor, and the voltage Vblc on the control gate may be referred to as a bit line clamp voltage. The source-follower mode can be used during sensing operations such as read and verify operations.

The time between t2 and t4 is used to develop the voltage on the sense node for a first sense development (SEN1 development). Between t2 and t4 S1 is high to open transistor T6, which is connected to SEN. The sense time (t3 to t4) is controlled by the signal XXL1, which is applied to the XXL1 transistor T1. Therefore, SEN is connected to the bit line by way of the XXL1 transistor T1 and BLC transistor T2. The bit line current will be the combined cell current of the two memory cells being sensed. The dashed arrow “first sensing” in FIG. 18 refers to the current pathway for sensing the bit value of one of the cells.

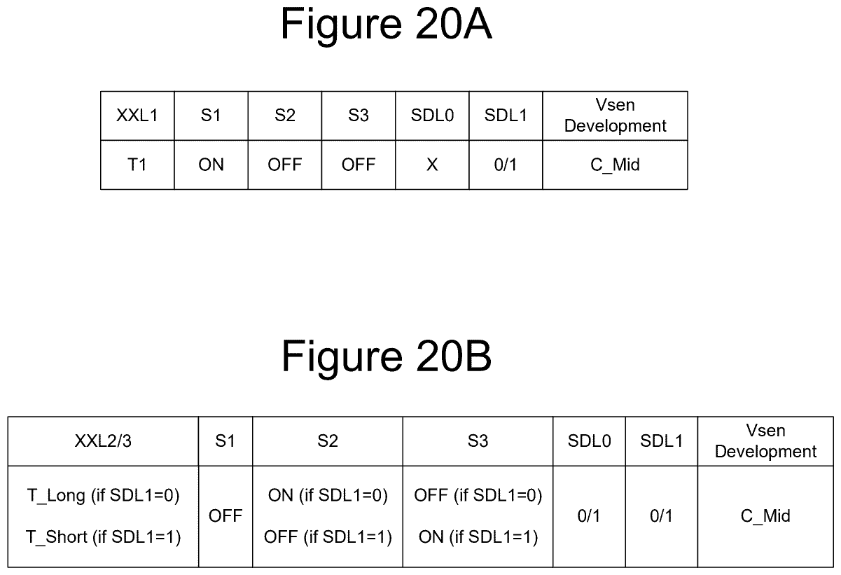

The time between t5 and t6 is used for storing a bit value for the first cell. This result will be stored in the SDL1 latch. Between t5 and t6 the signal STB is high to turn on the strobe transistor T7, which is connected to SEN tr. The sense transistor (SEN tr) is used to test the magnitude of the voltage on SEN. Specifically, strobe transistor T7 is turned on by STB to test the magnitude of the voltage on SEN. This result is then passed to SDL1. Therefore, the MSB is stored in SDL1. FIG. 20A summarizes the parameters for sensing the first bit value for an embodiment of the sense amplifier in FIG. 18.

Next, the bit value for the second cell is sensed by the choice of the sense time. Referring to FIG. 18 note that there are two current paths labeled second sensing. Only one of these paths will be used for a particular operation. The choice of which path (XXL2/S2 or XXL3/S3) is used depends on the bit value of the first cell. Logic gates 1802, 1804 are used to generate the signals S2, S3. The signal S2 will be high (with S3 low) if XXL2/S2 is to be used for the LSB. The signal S3 will be high (with S2 low) if XXL3/S3 is to be used for the LSB.

The time between t7 and t9 is used to again pre-charge the sense node SEN. Between t7 and t8 the signal SPC is high to turn on transistor T5. Transistor T5 is connected to a voltage VHLB, which pre-charges SEN. Between t9 and t13 the voltage on SEN is allowed to discharge. First the case in which XXL2/S2 is to be used for the LSB will be discussed. Between t9 to t13, S2 is high to open transistor T8, which is connected to SEN. The sense time (t10 to t13) is controlled by the signal XXL2, which is applied to the XXL2 transistor T9. Therefore, SEN is connected to the bit line by way of the XXL2 transistor T9 and BLC transistor T2. The bit line current will be the combined cell current of the two memory cells being sensed. The dashed arrow “second sensing” through T8 and T9 in FIG. 18 refers to the current pathway for sensing the bit value for the second cell. The time between t14 and t15 is used for storing the bit value for the second cell. This result will be stored in the SDL0 latch. Between t14 and t15 the signal STB is high to turn on strobe transistor T7, which is connected to SEN. The sense transistor is used to test the magnitude of the voltage on SEN. Specifically, strobe transistor T7 is turned on by STB to test the magnitude of the voltage on SEN. This result is then passed to SDL0. Therefore, the bit value for the second cell is stored in SDL0 for the example of using XXL2/S2.

Next the alternative case in which XXL3/S3 is to be used for determining the bit value for the second cell will be discussed. Between t9 to t13, S3 is high to open transistor T10, which is connected to SEN. The sense time (t1 to t12) is controlled by the signal XXL3, which is applied to the XXL3 transistor T11. Therefore, SEN is connected to the bit line by way of the XXL3 transistor T11 and BLC transistor T2. The bit line current will be the combined cell current of the two memory cells being sensed. The dashed arrow “second sensing” through T10 and T11 in FIG. 18 refers to the current pathway for sensing the bit value for the second cell. The time between t14 and t15 is used for storing the bit value for the second cell. This result will be stored in the SDL0 latch. Between t14 and t15 the signal STB is high to turn on strobe transistor T7, which is connected to SEN. The sense transistor is used to test the magnitude of the voltage on SEN. Specifically, strobe transistor T7 is turned on by STB to test the magnitude of the voltage on SEN. This result is then passed to SDL0. Therefore, the LSB is stored in SDL0 for the example of using XXL3/S3. FIG. 20B summarizes the parameters for sensing the bit value for the second cell for an embodiment of the sense amplifier in FIG. 18. Referring again to FIG. 19, the bit value in SDL0 is transferred to XDL0 and the bit value in SDL1 is transferred to XDL1 to complete the sensing process. Transistors T12 and T13 may be used in the bit transfers, using signals DSW1 and DSW2, respectively. Briefly, another feature of the sense amplifier 325 is to charge the bit line to a suitable voltage to either enable programming or inhibit programming. Transistors T14 and T15 may be used to pass either SRCGND (to enable programming) or VHSA (to inhibit programming).

An HBF 100 has been proposed. Numerous modifications to the above description are possible. Several examples have been provided in which the combined currents of two memory cells on two different NAND strings are sensed together as a bit line current. This concept may be extended to sensing the combined currents of three (or more) memory cells on three (or more) different NAND strings whose channels are connected to the same bit line.

One embodiment includes an apparatus comprising a memory structure comprising bit lines and NAND strings having memory cells. Each NAND string is associated with a bit line. The apparatus has one or more control circuits in communication with the memory structure. The one or more control circuits are configured to apply a reference voltage to multiple memory cells with one memory cell per NAND string. The one or more control circuits are configured to sense a combined current of the multiple memory cells in response to the reference voltage. The one or more control circuits are configured to determine a bit value of each of the multiple memory cells based on a magnitude of the combined current.

In one example implementation of the apparatus, the one or more control circuits are configured to: determine a first bit value for a first memory cell of the multiple memory cells by determining whether the magnitude of the combined current is above or below a first current magnitude; determine a second current magnitude to test for based on the first bit value; and determine a second bit value for a second memory cell of the multiple memory cells by determining whether the magnitude of the combined current is above or below the second current magnitude.

In one example implementation of the apparatus the multiple memory cells are a pair of the memory cells having a first memory cell on a first NAND string and a second memory cell on a second NAND string. The first NAND string and the second NAND string are connected to the same bit line. And, the one or more control circuits are configured to program the pair of the memory cells into one of three current states having different target magnitudes. A combined magnitude of the programmed current of the pair of the memory cells has four possible combined target magnitudes.

In one example implementation of the apparatus the one or more control circuits are configured to demarcate between the four possible combined target magnitudes for the sensed combined current for the pair of the memory cells. The one or more control circuits are configured to determine a bit value for each member of the pair of the memory cells based on demarcating between the four possible combined target magnitudes.

In one example implementation of the apparatus the three current states comprise: a first current state having a first target magnitude that corresponds to a first data state; a second current state having a second target magnitude that corresponds to a second data state; and a third current state having a third target magnitude that corresponds to the second data state.

In one example implementation of the apparatus the first current state is a non-conducting state in response to applying the reference voltage to a memory cell, the second current state is a conducting state in response to applying the reference voltage to a memory cell, and the third current state is a conducting state in response to applying the reference voltage to a memory cell.

In one example implementation of the apparatus the one or more control circuits are configured to program the first member of the pair of memory cells to the second current state responsive to a determination to program the first member to the second data state. And the one or more control circuits are configured to program the second member of the pair of memory cells to the third current state responsive to a determination to program the second member to the second data state.

In one example implementation of the apparatus the one or more control circuits are configured to program the first memory cell of the pair of memory cells to the first current state responsive to a determination to program the first memory cell to the first data state. And the one or more control circuits are configured to program the second memory cell of the pair of memory cells to the first current state responsive to a determination to program the second memory cell to the first data state.

In one example implementation of the apparatus the one or more control circuits comprise a plurality of sense amplifiers. Each sense amplifier is configured to sense a current in a bit line. Each sense amplifier comprises a first sense node, a second sense node and a third sense node having different capacitances. Each sense amplifier is configured to demarcate between the four possible combined target magnitudes based on applying the combined current of a pair of the memory cells to the first sense node, the second sense node and the third sense node for a fixed sense time.

In one example implementation of the apparatus the one or more control circuits are configured to determine a first bit value of the first memory cell of the pair of the memory cells based on applying the combined current to the second sense node for the fixed sense time; select either the first sense node or the third sense node based the first bit value; and determine a second bit value of the second memory cell of the pair of memory cells based on applying the combined current to the selected one of first sense node or the third sense node for the fixed sense time.

In one example implementation of the apparatus the one or more control circuits comprise a plurality of sense amplifiers. Each sense amplifier is configured to sense a current in a bit line. Each sense amplifier comprises a sense node. Each sense amplifier is configured to demarcate between the four possible combined target magnitudes based on applying the current in the bit line to the sense node for three different sense times that include a first sense time, a second sense time, and a third sense time having different lengths.

In one example implementation of the apparatus the one or more control circuits are configured to: determine a first bit value of the first memory cell of the pair of the memory cells based on applying the current in the bit line to the sense node for the second sense time; determine whether to use a result of applying the bit line current to the sense node for the first sense time or the third sense time based on the first bit value; and determine a second bit value of the second memory cell of the pair of memory cells based on applying the bit line current to the determined first sense time or third sense time.

An embodiment includes a method of operating non-volatile memory. The method comprises programming memory cells on a first group of NAND strings to either a non-conducting current state to represent a first bit value or a first conducting state having a first current magnitude to represent a second bit value. The method comprises programming memory cells on a second group of NAND strings to either the non-conducting current state to represent the first bit value or a second conducting state having a second current magnitude to represent the second bit value. The method comprises sensing combined currents in pairs of the memory cells in response to a reference voltage. Each pair has a first memory cell in the first group of NAND strings and a second memory cells in the second group of NAND strings. The method comprises determining, for each pair of memory cells, a first bit value for the first memory cell in the pair and a second bit value for the second memory cell in the pair based on a magnitude of the combined current for the pair of memory cells.

An embodiment includes a non-volatile storage system, comprising a memory structure comprising NAND strings and bit lines. Each NAND string has memory cells. The NAND strings comprise a first group and a second group. The NAND strings comprise pairs with each pair associated with the same bit line. Each pair of NAND strings has a first memory cell in the first group of NAND strings and a second memory cell in the second group of NAND strings. The non-volatile storage system has one or more control circuits in communication with the memory structure. The one or more control circuits are configured to program selected memory cells on the first group of NAND strings and the second group of NAND strings into one of three current states having different target magnitudes. A combined target current magnitude of each pair of the selected memory cells on a corresponding pair of the NAND strings connected to the same bit line has four possible combined target current magnitudes. The one or more control circuits are configured to apply a reference voltage to the selected memory cells on the first group and the second group of the NAND strings while connecting channels of each pair of the NAND strings to the same bit line. The one or more control circuits are configured to sense a current in each bit line responsive to the reference voltage applied to the selected memory cells. The one or more control circuits are configured to, for each pair of the selected memory cells, determine a first bit value for a first memory cell of the pair and a second bit value for a second memory cell of the pair based on a magnitude of the bit line current for that pair of the selected memory cells.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects. For purposes of this document, the term “subset” of objects refers to at least one of the objects in the set and may include all of the objects in the set.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a memory structure comprising bit lines and NAND strings having memory cells, each NAND string associated with a bit line; and
one or more control circuits in communication with the memory structure, wherein the one or more control circuits are configured to:
apply a reference voltage to multiple memory cells with one memory cell per NAND string;
sense a combined current of the multiple memory cells in response to the reference voltage; and
determine a bit value of each of the multiple memory cells based on a magnitude of the combined current.

2. The apparatus of claim 1, wherein the one or more control circuits are configured to:
determine a first bit value for a first memory cell of the multiple memory cells by determining whether the magnitude of the combined current is above or below a first current magnitude;
determine a second current magnitude to test for based on the first bit value; and
determine a second bit value for a second memory cell of the multiple memory cells by determining whether the magnitude of the combined current is above or below the second current magnitude.

3. The apparatus of claim 1, wherein:
the multiple memory cells are a pair of the memory cells having a first memory cell on a first NAND string and a second memory cell on a second NAND string, the first NAND string and the second NAND string connected to the same bit line; and
the one or more control circuits are configured to program the pair of the memory cells into one of three current states having different target magnitudes, wherein a combined magnitude of the programmed current of the pair of the memory cells has four possible combined target magnitudes.

4. The apparatus of claim 3, wherein the one or more control circuits are configured to:
demarcate between the four possible combined target magnitudes for the sensed combined current for the pair of the memory cells; and
determine a bit value for each member of the pair of the memory cells based on demarcating between the four possible combined target magnitudes.

5. The apparatus of claim 3, wherein the three current states comprise:
a first current state having a first target magnitude that corresponds to a first data state;
a second current state having a second target magnitude that corresponds to a second data state; and
a third current state having a third target magnitude that corresponds to the second data state.

6. The apparatus of claim 5, wherein:
the first current state is a non-conducting state in response to applying the reference voltage to a memory cell;
the second current state is a conducting state in response to applying the reference voltage to a memory cell; and
the third current state is a conducting state in response to applying the reference voltage to a memory cell.

7. The apparatus of claim 5, wherein the one or more control circuits are configured to:
program the first memory cell of the pair of memory cells to the second current state responsive to a determination to program the first memory cell to the second data state; and
program the second memory cell of the pair of memory cells to the third current state responsive to a determination to program the second memory cell to the second data state.

8. The apparatus of claim 7, wherein the one or more control circuits are configured to:
program the first memory cell of the pair of memory cells to the first current state responsive to a determination to program the first memory cell to the first data state; and
program the second memory cell of the pair of memory cells to the first current state responsive to a determination to program the second memory cell to the first data state.

9. The apparatus of claim 3, wherein the one or more control circuits comprise a plurality of sense amplifiers, each sense amplifier configured to sense a current in a bit line, wherein each sense amplifier comprises:
a first sense node, a second sense node and a third sense node having different capacitances, each sense amplifier configured to demarcate between the four possible combined target magnitudes based on applying the combined current of a pair of the memory cells to the first sense node, the second sense node and the third sense node for a fixed sense time.

10. The apparatus of claim 9, wherein the one or more control circuits are configured to:
determine a first bit value of the first memory cell of the pair of the memory cells based on applying the combined current to the second sense node for the fixed sense time;
select either the first sense node or the third sense node based the first bit value; and
determine a second bit value of the second memory cell of the pair of memory cells based on applying the combined current to the selected one of first sense node or the third sense node for the fixed sense time.

11. The apparatus of claim 3, wherein the one or more control circuits comprise a plurality of sense amplifiers, each sense amplifier configured to sense a current in a bit line, each sense amplifier comprises:
a sense node, each sense amplifier configured to demarcate between the four possible combined target magnitudes based on applying the current in the bit line to the sense node for three different sense times that include a first sense time, a second sense time, and a third sense time having different lengths.

12. The apparatus of claim 11, wherein the one or more control circuits are configured to:
determine a first bit value of the first memory cell of the pair of the memory cells based on applying the current in the bit line to the sense node for the second sense time;
determine whether to use a result of applying the bit line current to the sense node for the first sense time or the third sense time based on the first bit value; and
determine a second bit value of the second memory cell of the pair of memory cells based on applying the bit line current to the determined first sense time or third sense time.

13. A method of operating non-volatile memory, the method comprising:
programming memory cells on a first group of NAND strings to either a non-conducting current state to represent a first bit value or a first conducting state having a first current magnitude to represent a second bit value;
programming memory cells on a second group of NAND strings to either the non-conducting current state to represent the first bit value or a second conducting state having a second current magnitude to represent the second bit value;
sensing combined currents in pairs of the memory cells in response to a reference voltage, wherein each pair has a first memory cell in the first group of NAND strings and a second memory cells in the second group of NAND strings; and
determining, for each pair of memory cells, a first bit value for the first memory cell in the pair and a second bit value for the second memory cell in the pair based on a magnitude of the combined current for the pair of memory cells.

14. The method of claim 13, wherein for each particular pair of the memory cells sensing the combined currents in the particular pair of the memory cells comprises:
connecting a first channel of a first NAND string having the first memory cell in the pair to a bit line while connecting a second channel of a second NAND string having the second memory cell in the pair to the bit line while and while applying the reference voltage to the first memory cell in the pair and the second memory cell in the pair; and
sensing a current in the bit line.

15. The method of claim 14, wherein for each particular pair of the memory cells determining a data state for the first memory cell of the particular pair and the second memory cell of the particular pair comprises:
determining a first bit value for the first memory cell of the particular pair based on applying the combined current to a first sense capacitor for an integration time; and
determining a second bit value for the second memory cell of the particular pair by:
selecting either a second sense capacitor or a third sense capacitor based on the first bit value, wherein the first sense capacitor, the second sense capacitor and the third sense capacitor each have a different capacitance; and
applying the combined current to selected one of the second sense capacitor or the third sense capacitor for the integration time.

16. The method of claim 14, wherein for each particular pair of the memory cells determining a data state for the first memory cell of the particular pair and the second memory cell of the particular pair comprises:
determining a first bit value for the first memory cell of the particular pair based on applying the combined current to a sense capacitor for a first integration time; and
determining a second bit value for the second memory cell of the particular pair by:
selecting either a second integration time or a third integration time based on the first bit value, wherein the first integration time, the second integration time and the third integration time each have a different length; and
applying the combined current to the sense capacitor for the selected one of the second integration time or the third integration time.

17. A non-volatile storage system, comprising:
a memory structure comprising NAND strings and bit lines, each NAND string having memory cells, the NAND strings comprising a first group and a second group, the NAND strings comprising pairs with each pair associated with the same bit line, each pair of NAND strings having a first memory cell in the first group of NAND strings and a second memory cell in the second group of NAND strings; and
one or more control circuits in communication with the memory structure, wherein the one or more control circuits are configured to:
program selected memory cells on the first group of NAND strings and the second group of NAND strings into one of three current states having different target magnitudes, wherein a combined target current magnitude of each pair of the selected memory cells on a corresponding pair of the NAND strings connected to the same bit line has four possible combined target current magnitudes;
apply a reference voltage to the selected memory cells on the first group and the second group of the NAND strings while connecting channels of each pair of the NAND strings to the same bit line;
sense a current in each bit line responsive to the reference voltage applied to the selected memory cells; and
for each pair of the selected memory cells, determine a first bit value for a first memory cell of the pair and a second bit value for a second memory cell of the pair based on a magnitude of the bit line current for that pair of the selected memory cells.

18. The non-volatile storage system of claim 17, wherein the one or more control circuits are configured to:
program first memory cells of the pairs of the memory cells to a first current state having a first target magnitude to store a first value for a first bit for the pair;
program the first memory cells of the pairs of the memory cells to a second current state having a second target magnitude to store a second value for the first bit for the pair;
program second memory cells of the pairs of the memory cells to the first current state to store the first value for a second bit for the pair; and
program the second memory cells of the pairs of the memory cells to a third current state having a third target magnitude to store a second value for the second bit for the pair.

19. The non-volatile storage system of claim 17, wherein the one or more control circuits comprise a plurality of sense amplifiers, each sense amplifier is configured to sense a current in a bit line associated with the sense amplifier, wherein each sense amplifier comprises:
a first sense node, a second sense node and a third sense node having different capacitances, each sense amplifier configured to demarcate between the four possible combined target current magnitudes based on applying the bit line current to the first sense node, the second sense node and the third sense node for a fixed sense time.

20. The non-volatile storage system of claim 17, wherein the one or more control circuits comprise a plurality of sense amplifiers, each sense amplifier is configured to sense a current in a bit line associated with the sense amplifier, wherein each sense amplifier comprises:
a sense node, each sense amplifier configured to demarcate between the four possible combined target current magnitudes based on applying the current in the bit line to the sense node for three different sense times that include a first sense time, a second sense time, and a third sense time having different lengths.
